(19) United States
(12) Patent Application Publication
(10) Pub. No.: US 2019/0287800 A1
(43) Pub. Date: Sep. 19, 2019

(54) GRAPHENE NANORIBBON PRECURSOR, GRAPHENE NANORIBBON, ELECTRONIC DEVICE, AND METHOD

(71) Applicant: FUJITSU LIMITED, Kawasaki-shi (JP)

(72) Inventor: Junichi Yamaguchi, Atsugi (JP)

(73) Assignee: FUJITSU LIMITED, Kawasaki-shi (JP)

(21) Appl. No.: 16/299,867

(22) Filed: Mar. 12, 2019

(30) Foreign Application Priority Data
Mar. 15, 2018 (JP) 2018-048185

(51) Int. Cl. H01L 21/02; H01L 29/06; H01L 29/16; H01L 29/786; H01L 29/88; C23C 16/26

(52) U.S. Cl. CPC H01L 21/02527; H01L 21/02603; H01L 21/02661; H01L 21/0262; C23C 16/26; H01L 29/1606; H01L 29/78684; H01L 29/78696; H01L 29/882; H01L 29/0673

(57) ABSTRACT

A graphene nanoribbon precursor has a structure that is indicated by a predetermined chemical formula. In the chemical formula (1), n₁ is an integer that is greater than or equal to 1 and less than or equal to 6; X, Y, and Z are F, Cl, Br, I, H, OH, SH, SO₂H, SO₃H, SO₂NH₂, PO₃H₂, NO, NO₂, NH₂, CH₃, CHO, COCH₃, COOH, CONH₂, COCl, CN, CF₃, CCl₃, CBr₃, or CI₃; and when desorption temperatures of X, Y and Z from carbon atoms constituting six-membered rings are respectively T_{X}, T_{Y}, and T_{Z}, a relationship of T_{X}<T_{Y}≤T_{Z} is satisfied.

### CROSS-REFERENCE TO RELATED APPLICATION

This application is based on and claims priority to Japanese Patent Application No. 2018-048185 filed on Mar. 15, 2018, the entire contents of which are incorporated herein by reference.

### FIELD

The embodiments discussed herein relate to a graphene nanoribbon precursor, a graphene nanoribbon, an electronic device, and a method.

Graphene is a material having a two-dimensional sheet structure in which C atoms are arranged in a honeycomb shape. Electron mobility and hole mobility of graphene are extremely high even at room temperature, and graphene has special electronic properties such as ballistic conduction and the anomalous quantum Hall effect. Because n conjugation is extended in two dimensions, the band gap of graphene is substantially zero, and graphene shows a metallic property (gapless semiconductor). In recent years, research and development of electronic devices making use of these characteristic electronic properties have been actively conducted.

Conversely, in nano-sized graphene, the difference between the number of C atoms at the edge and the number of C atoms inside the edge is small. Thus, such nano-sized graphene is greatly affected by a shape of the graphene itself and a shape of the edge, and shows a physical property greatly differing from that of bulky graphene. As nano-sized graphene, a quasi-one-dimensional graphene of a ribbon shape with a width of several nm, which is called a graphene nanoribbon (GNR) is known. The physical property of a GNR varies greatly depending on the edge structure and the ribbon width.

There are two types of edge structures of GNRs: an armchair edge in which C atoms are arranged in two atomic cycles; and a zigzag edge in which C atoms are arranged in a zigzag pattern. In an armchair edge type GNR (AGNR), because the finite band gap opens due to the quantum confinement effect and edge effect, the AGNR shows a semiconductive property. Conversely, a zigzag edge type GNR (ZGNR) shows a metallic property.

In general, an AGNR where the number of C—C dimer lines in the ribbon width direction is N is called a “N-AGNR”. For example, an AGNR whose basic unit is anthracene in which three six-membered rings are arranged in the ribbon width direction is called a 7-AGNR. AGNRs may be classified, depending on the values of N, into three subfamilies that are N=3p, N=3p+1, and N=3p+2 (where p is a positive integer). First-principles calculations considering many-body effects show that the bandgap E_{g} of N-AGNRs within the same subfamily decreases in accordance with an increase in the value of N, that is, in accordance with an increase in the ribbon width. Also, the band gaps E_{g} between each subfamily have a relationship of “E_{g}^{3p+1}>E_{g}^{3p}>E_{g}^{3p+2}”.

Although various methods such as a bottom-up method have been proposed in order to produce AGNRs having desired physical properties, AGNRs with a length that can be used for electronic devices have not been produced. That is, the applicable range of conventional AGNRs is limited.

### RELATED-ART DOCUMENTS

### Patent Documents

[Patent Document 1] Japanese National Publication of International Patent Application No. 2015-525186
[Patent Document 2] Japanese National Publication of International Patent Application No. 2017-520618

### Non-Patent Documents

[Non-Patent Document 1] J. Cai et al., Nature 466, 470 (2010)
[Non-Patent Document 2] Y.-C. Chen et al., ACS Nano 7, 6123 (2013)

### SUMMARY

According to an aspect of the embodiments, a graphene nanoribbon precursor has a structure that is indicated by a following chemical formula (1).

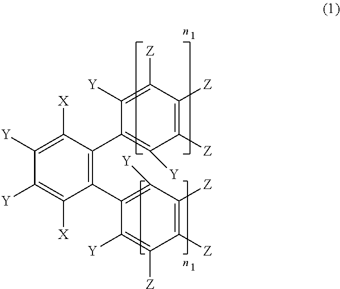

In the above chemical formula (1), n₁ is an integer that is greater than or equal to 1 and less than or equal to 6; X, Y, and Z are F, Cl, Br, I, H, OH, SH, SO₂H, SO₃H, SO₂NH₂, PO₃H₂, NO, NO₂, NH₂, CH₃, CHO, COCH₃, COOH, CONH₂, COCl, CN, CF₃, CCl₃, CBr₃, or CI₃; and when desorption temperatures of X, Y and Z from carbon atoms constituting six-membered rings are respectively T_{X}, T_{Y}, and T_{Z}, a relationship of T_{X}<T_{Y}≤T_{Z} is satisfied.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a diagram illustrating a structural formula of a GNR precursor according to a first embodiment;

FIG. 2A is a diagram illustrating a method of producing a GNR using GNR precursors according to the first embodiment (1);

FIG. 2B is a diagram illustrating the method of producing the GNR using the GNR precursors according to the first embodiment (2);

FIG. 2C is a diagram illustrating the method of producing the GNR using the GNR precursors according to the first embodiment (3);

FIG. 3A is a diagram illustrating a method of producing the GNR precursor according to the first embodiment (1);

FIG. 3B is a diagram illustrating the method of producing the GNR precursor according to the first embodiment (2);

FIG. 4A is a diagram illustrating a structural formula of a material of a GNR precursor according to the first embodiment (1);

FIG. 4B is a diagram illustrating a structural formula of a material of the GNR precursor according to the first embodiment (2);

FIG. 5 is a diagram illustrating a structural formula of a GNR precursor according to a second embodiment;

FIG. 6A is a diagram illustrating a method of producing a GNR using GNR precursors according to the second embodiment (1);

FIG. 6B is a diagram illustrating the method of producing the GNR using the GNR precursors according to the second embodiment (2);

FIG. 7A is a diagram illustrating a topographic image of the GNR according to the second embodiment (1);

FIG. 7B is a diagram illustrating a topographic image of the GNR according to the second embodiment (2);

FIG. 8A is a diagram illustrating a method of producing the GNR precursor according to the second embodiment (1);

FIG. 8B is a diagram illustrating the method of producing the GNR precursor according to the second embodiment (2);

FIG. 8C is a diagram illustrating the method of producing the GNR precursor according to the second embodiment (3);

FIG. 9 is a diagram illustrating a structural formula of a GNR precursor according to a third embodiment;

FIG. 10A is a diagram illustrating a method of producing a GNR using GNR precursors according to the third embodiment (1);

FIG. 10B is a diagram illustrating the method of producing the GNR using the GNR precursors according to the third embodiment (2);

FIG. 11A is a diagram illustrating a topographic image of the GNR according to the third embodiment (1);

FIG. 11B is a diagram illustrating a topographic image of the GNR according to the third embodiment (2);

FIG. 12A is a diagram illustrating a method of producing the GNR precursor according to the third embodiment (1);

FIG. 12B is a diagram illustrating the method of producing the GNR precursor according to the third embodiment (2);

FIG. 12C is a diagram illustrating the method of producing the GNR precursor according to the third embodiment (3);

FIG. 13 is a diagram illustrating a structural formula of a GNR precursor according to a fourth embodiment;

FIG. 14A is a diagram illustrating a method of producing a GNR using GNR precursors according to the fourth embodiment (1);

FIG. 14B is a diagram illustrating the method of producing the GNR using the GNR precursors according to the fourth embodiment (2);

FIG. 15A is a diagram illustrating a method of producing the GNR precursor according to the fourth embodiment (1);

FIG. 15B is a diagram illustrating the method of producing the GNR precursor according to the fourth embodiment (2);

FIG. 15C is a diagram illustrating the method of producing the GNR precursor according to the fourth embodiment (3);

FIG. 16 is a diagram illustrating a relationship between a C—C dimer line and a ribbon width W;

FIG. 17A is a top view illustrating a method of producing an electronic device according to a fifth embodiment (1);

FIG. 17B is a top view illustrating the method of producing the electronic device according to the fifth embodiment (2);

FIG. 17C is a top view illustrating the method of producing the electronic device according to the fifth embodiment (3);

FIG. 17D is a top view illustrating the method of producing the electronic device according to the fifth embodiment (4);

FIG. 17E is a top view illustrating the method of producing the electronic device according to the fifth embodiment (5);

FIG. 18 is a diagram illustrating a positional relationship between a metal pattern and an N-AGNR according to the fifth embodiment;

FIG. 19A is a cross-sectional view illustrating the method of producing the electronic device according to the fifth embodiment (1);

FIG. 19B is a cross-sectional view illustrating the method of producing the electronic device according to the fifth embodiment (2);

FIG. 20A is a top view illustrating the method of producing the electronic device according to a sixth embodiment (1);

FIG. 20B is a top view illustrating the method of producing the electronic device according to the sixth embodiment (2);

FIG. 20C is a top view illustrating the method of producing the electronic device according to the sixth embodiment (3);

FIG. 20D is a top view illustrating the method of producing the electronic device according to the sixth embodiment (4);

FIG. 20E is a top view illustrating a method of producing the electronic device according to the sixth embodiment (5);

FIG. 21 is a diagram illustrating a positional relationship between a metal pattern and an N-AGNR according to the sixth embodiment;

FIG. 22A is a cross-sectional view illustrating the method of producing the electronic device according to the sixth embodiment (1);

FIG. 22B is a cross-sectional view illustrating the method of producing the electronic device according to the sixth embodiment (2);

FIG. 22C is a cross-sectional view illustrating the method of producing the electronic device according to the sixth embodiment (3); and

FIG. 23 is a diagram illustrating a band structure of a heterojunction AGNR according to the sixth embodiment.

### DESCRIPTION OF EMBODIMENT

In the following, embodiments will be described in detail with reference to the attached drawings.

### First Embodiment

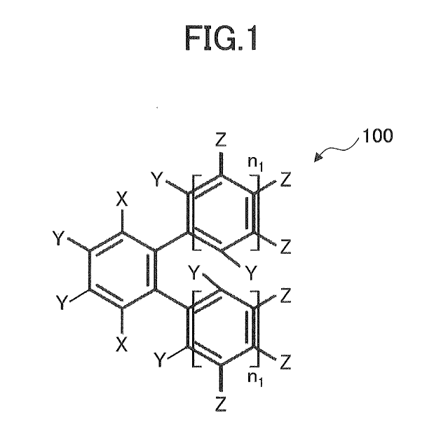

First, a first embodiment will be described. The first embodiment relates to a graphene nanoribbon (GNR) and a GNR precursor that is suitable for producing the GNR. FIG. 1 is a diagram illustrating a structural formula of a GNR precursor 100 according to the first embodiment.

The GNR precursor 100 according to the first embodiment has the structure illustrated in FIG. 1. In FIG. 1, n₁ is an integer that is greater than or equal to 1 and less than or equal to 6. X, Y, and Z are F, Cl, Br, I, H, OH, SH, SO₂H, SO₃H, SO₂NH₂, PO₃H₂, NO, NO₂, NH₂, CH₃, CHO, COCH₃, COOH, CONH₂, COCl, CN, CF₃, CCl₃, CBr₃, or CI₃. When desorption temperatures of X, Y and Z from carbon atoms constituting six-membered rings are respectively T_{X}, T_{Y}, and T_{Z}, a relationship of T_{X}<T_{Y}≤T_{Z} is satisfied.

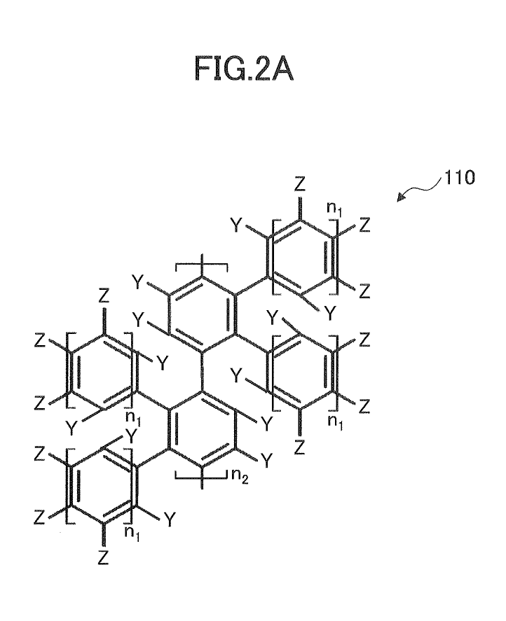

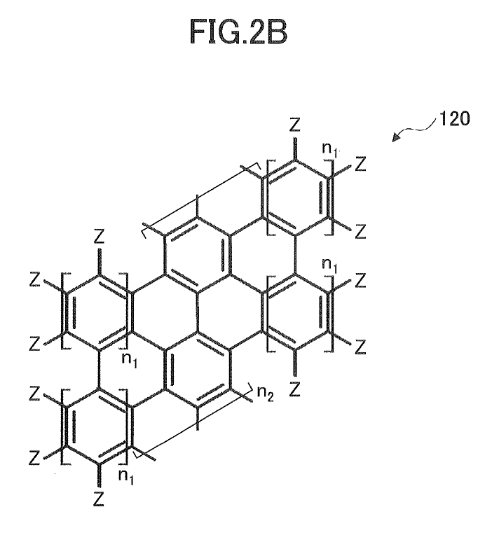

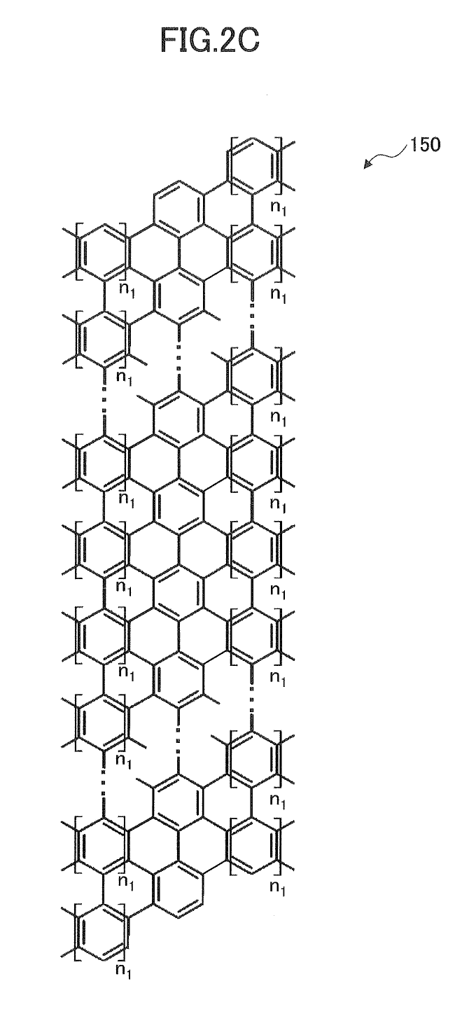

Here, a method of producing a GNR using the GNR precursors 100 according to the first embodiment will be described. FIG. 2A to FIG. 2C are diagrams illustrating a method of producing a GNR using the GNR precursors 100 according to the first embodiment. In this method the AGNR is produced in situ.

First, a surface cleaning process of a substrate on which a GNR is grown is performed. By the surface cleaning process, organic contaminants on the surface of the substrate can be removed and the surface flatness can be enhanced.

Next, without exposing the substrate, on which the surface cleaning treatment has been performed, to the atmosphere, under vacuum, the temperature of the substrate is held at a first temperature, which is greater than or equal to the desorption temperature T_{X} and less than the desorption temperature T_{Y}, to heat and sublimate the GNR precursors 100. De-X reaction and C—C bonding reaction of the GNR precursors 100 are induced on the substrate at the first temperature, and as illustrated in FIG. 2A, a polymer 110, in which a plurality of molecules of the GNR precursors 100 are arranged in one direction while turning back the direction of protrusion, is stably formed.

Thereafter, the temperature of the substrate is heated to a second temperature, which is greater than or equal to the desorption temperature T_{Y} and less than the desorption temperature T_{Z}, and is held at the second temperature. As a result, de-Y reaction and cyclization reaction are induced, and as illustrated in FIG. 2B, a polymer 120 is stably formed from the polymer 110.

Subsequently, the temperature of the substrate is heated to a third temperature, which is greater than or equal to the desorption temperature T_{Z}, and is held at the third temperature. As a result, de-Z reaction and cyclization reaction are induced, and as illustrated in FIG. 2C, an AGNR 150 whose edge structure is of armchair type is formed from the polymer 120.

When the desorption temperature T_{Y} is equal to the desorption temperature T_{Z}, the second temperature may be set to be greater than the desorption temperature T_{Y} and desorption temperature T_{Y}. By setting the second temperature greater than or equal to the desorption temperature T_{Y} and desorption temperature T_{Y}, the formation of the polymer 120 is omitted, and the AGNR 150 is formed from the polymer 110.

In this way, upon heating the GNR precursors 100, X's are detached and C's, from which X's are detached, are bonded with each other between the GNR precursors 100. Thereafter, Y's are detached, and C's, from which Y's are detached, are bonded with each other between the GNR precursors 100, and Z's are detached, and C's, from which Z's are detached, are bonded with each other between the GNR precursors 100. A sequence (array) of the GNR precursors 100 is determined by bonding C's, to which X's have been bonded, with each other and thereafter, a structure of the AGNR 150 is fixed by bonding C's, to which Y's and Z's have been bonded, with each other. Therefore, it is possible to stably synthesize a long AGNR 150. For example, it is possible to stably synthesize an AGNR 150 on an order of several tens of nm. Therefore, by using the GNR precursors 100 according to the first embodiment, a long AGNR 150 can be produced by a bottom-up method. Note that the AGNR 150 is composed of a repeat unit having a structure that is indicated by the following chemical formula (2).

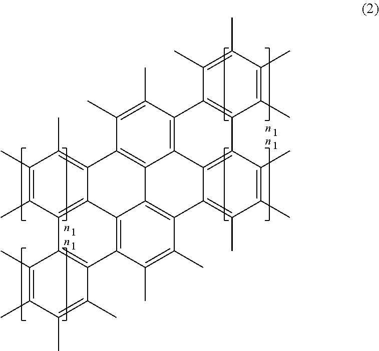

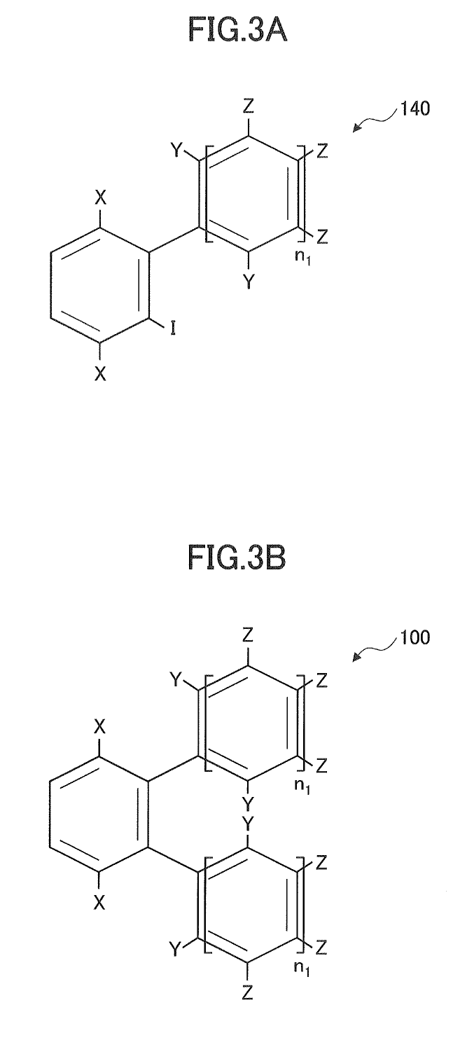

Next, a method of producing the GNR precursor 100 according to the first embodiment will be described. FIG. 3A and FIG. 3B are diagrams illustrating a method of producing the GNR precursor 100 according to the first embodiment.

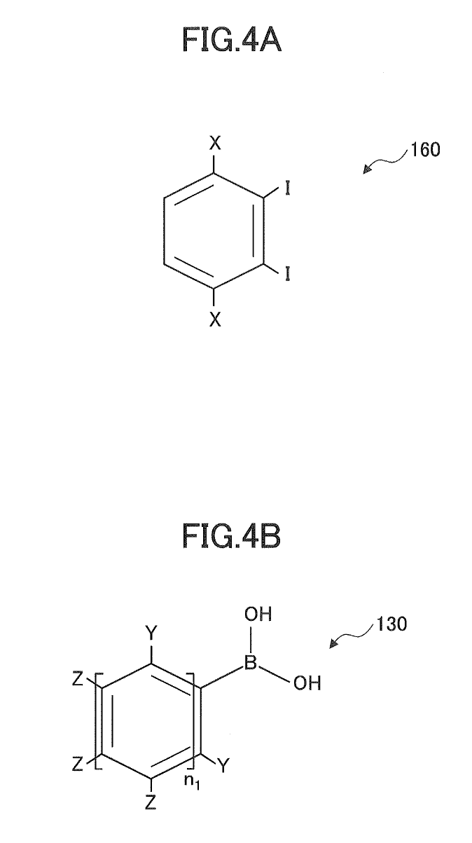

First, a substance 160 indicated by the structural formula in FIG. 4A and a substance 130 indicated by the structural formula in FIG. 4B are prepared. The substance 160, which is illustrated in FIG. 4A, may be, for example, 1,4-dibromo-2,3-diiodobenzene. The substance 130, which is illustrated in FIG. 4B, may be, for example, a boronic acid of benzene, naphthalene, anthracene, naphthacene, pentacene or hexacene.

Next, the substance 160 and the substance 130 are dissolved in a solvent, a catalyst is added and stirred in the presence of a base to cause a Suzuki coupling reaction. By continuing stirring to evaporate the solvent, as illustrated in FIG. 3A, a substance 140 having a bond at a location of one iodine (I) contained in the substance 160.

Thereafter, the substance 140 illustrated in FIG. 3A and the substance 130 are dissolved in a solvent, a catalyst is added and stirred in the presence of a base to cause a Suzuki coupling reaction. By continuing stirring to evaporate the solvent, as illustrated in FIG. 3B, the GNR precursor 100 having a bond at a location of one iodine (I) contained in the substance 140 is obtained.

Then, purification of the GNR precursor 100 is carried out, for example, by column chromatography.

In this way, the GNR precursor 100 can be produced.

### Second Embodiment

Next, a second embodiment will be described. The second embodiment relates to a GNR and a GNR precursor that is suitable for producing the GNR. FIG. 5 is a diagram illustrating a structural formula of a GNR precursor 200 according to the second embodiment.

The GNR precursor 200 according to the second embodiment a the structure illustrated in FIG. 5. That is, the GNR precursor 200 according to the second embodiment has the structure indicated by a structural formula in which n₁ is 2, X is Br, and Y and Z are H in FIG. 1. The desorption temperature of Br from the carbon atoms constituting a six-membered ring is lower than the desorption temperature of H from the carbon atoms constituting a six-membered ring. The GNR precursor 200 is 1,2-bis-(2-naphthalenyl)-3,6-dibromobenzene.

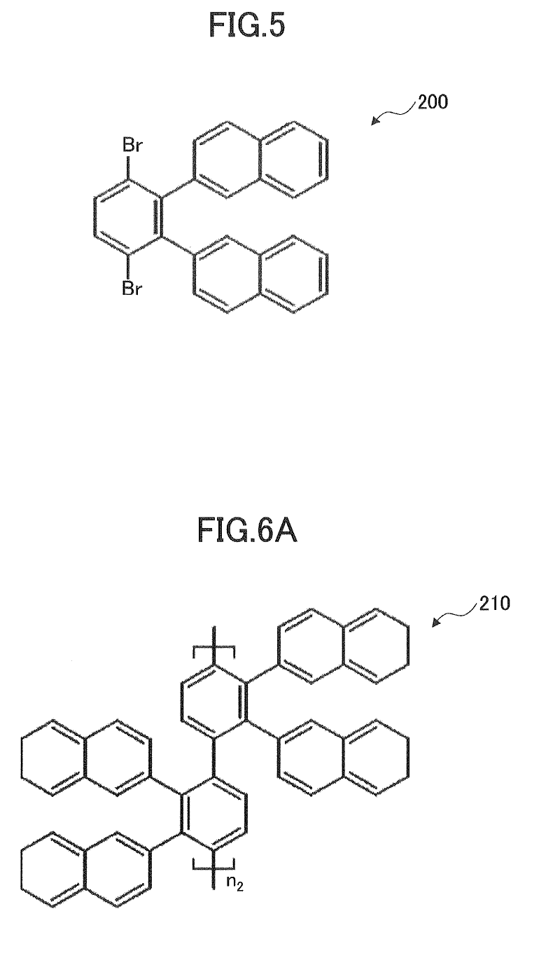

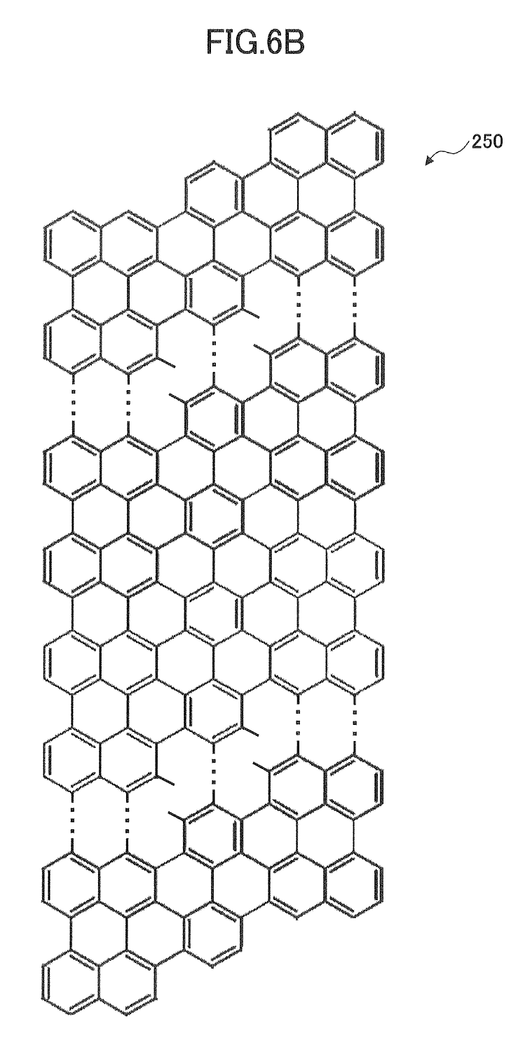

Here, a method of producing a GNR using the GNR precursors 200 according to the second embodiment will be described. FIG. 6A and FIG. 6B are diagrams illustrating a method of producing a GNR using the GNR precursors 200 according to the second embodiment. In this method a 13-AGNR is produced in situ.

First, a surface cleaning process of a substrate on which a GNR is grown is performed. In this surface cleaning process, for example, Ar ion sputtering to the surface and annealing under ultrahigh vacuum are set as one cycle, and this cycle is performed for a plurality of cycles. For example, in each cycle, in the Ar ion sputtering, the ion acceleration voltage is set to 1.0 kV, the ion current is set to 10 μA, the time is set to 1 minute, and in the annealing, while maintaining the degree of vacuum of 5×10⁻⁷ Pa or less, the temperature is set to 400° C. to 500° C. and the time is set to 10 minutes. For example, the number of cycles is three (three cycles). By the surface cleaning process, organic contaminants on the surface of the substrate can be removed and the surface flatness can be enhanced.

Next, without exposing the substrate, on which the surface cleaning treatment has been performed, to the atmosphere, under ultra-high vacuum, the temperature of the substrate is held at a first temperature, which is greater than or equal to the desorption temperature of Br and less than the desorption temperature of H, to heat and sublimate the GNR precursors 200. For example, the base pressure in a vacuum chamber is set to less than or equal to 5×10⁻⁸ Pa and the first temperature is set in a range of 150° C. to 250° C.; additionally, a K-cell type evaporator is used to heat and sublimate the GNR precursors 200, and the heating temperature of the GNR precursors 200 is set to approximately 90° C.

De-Br reaction and C—C bonding reaction of the GNR precursors 200 are induced on the substrate at the first temperature, and as illustrated in FIG. 6A, a polymer 210, in which a plurality of molecules of the GNR precursors 200 are arranged in one direction while turning back the direction of protrusion, is stably formed. For example, at this time, the deposition rate is in a range of 0.01 nm/min to 0.05 nm/min, and the vapor deposition thickness is in a range of 0.5 ML to 1 ML. Here, 1 ML (monolayer) is approximately 0.25 nm.

Subsequently, the temperature of the substrate is heated to a second temperature, which is greater than or equal to the desorption temperature of H, and is held at the second temperature. As a result, de-H reaction and cyclization reaction are induced, and as illustrated in FIG. 6B, a 13-AGNR 250 whose edge structure is of armchair type is formed from the polymer 210. For example, the second temperature is set in a range of 350° C. to 450° C., the heating rate from the first temperature to the second temperature is set in a range of 1° C./min to 5° C./min, and the holding time at the second temperature is set in a range of 10 minutes to 1 hour.

In this way, upon heating the GNR precursors 200, Br's are detached and C's, from which Br's are detached, are bonded with each other between the GNR precursors 200. Thereafter, H's are detached, and C's, from which H's are detached, are bonded with each other between the GNR precursors 200. A sequence (array) of the GNR precursors 200 is determined by bonding C's, to which Br's have been bonded, with each other and thereafter, a structure of the 13-AGNR 250 is fixed by bonding C's, to which H's have been bonded, with each other. Therefore, it is possible to stably synthesize a long 13-AGNR 250. For example, it is possible to stably synthesize a 13-AGNR 250 on an order of several tens of nm. Therefore, by using the GNR precursors 200 according to the second embodiment, a long 13-AGNR 250 can be produced by a bottom-up method.

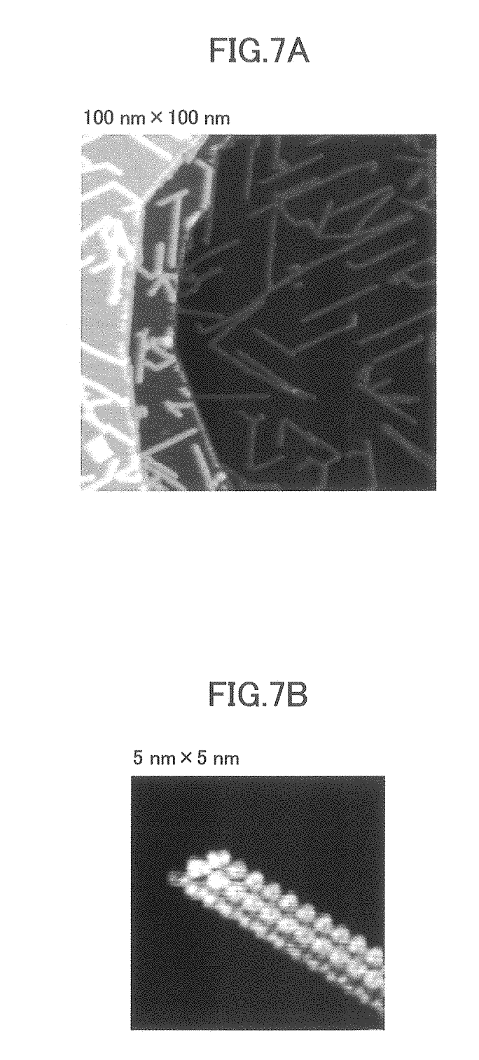

FIG. 7A and FIG. 7B illustrate topographic images of a 13-AGNR, produced according to the second embodiment, taken by a scanning tunneling microscope (STM). The scan area in FIG. 7A is 100 nm×100 nm, and in this picture, a sample bias Vₛ is set to 2.0 V and a tunnel current Iₜ is set to 30 pA. The scan area in FIG. 7B is 5 nm×5 nm, and in this picture, a sample bias Vₛ is set to −1.8 V and a tunnel current Iₜ is set to 7.1 nA. The 13-AGNR is synthesized on an Au (111) substrate, and as illustrated in FIG. 7A and FIG. 7B, the 13-AGNR with a ribbon length in a range of 20 nm to 50 nm can be synthesized. According to first principles simulation considering many-body effects, the band gap E_{g} of the 13-AGNR is estimated to be 2.34 eV.

As the substrate, a substrate having a catalytic function is used, and for example, a metal single-crystal substrate having a Miller index (111) on the surface can be used. Examples of a material for the substrate include Au, Cu, Ni, Rh, Pd, Ag, Ir and Pt. In order to control the directivity of the 13-AGNR 250, a high-index single-crystal substrate having a step width of several nanometers and a terrace periodic structure may be used. The Miller index of the surface of such a substrate is, for example, (788). As the substrate, a metal thin film substrate obtained by depositing a metal thin film, such as Au, on an insulating substrate, such as mica, sapphire, MgO, may be used. In order to control the directivity of the 13-AGNR 250, a metal thin film patterned into a thin line shape with a width of several nm by electron beam lithography and etching processing may be used. A substrate made of semiconductor such as a group IV semiconductor, a group III-V compound semiconductor, a group II-VI compound semiconductor, and a transition metal oxide semiconductor may be used.

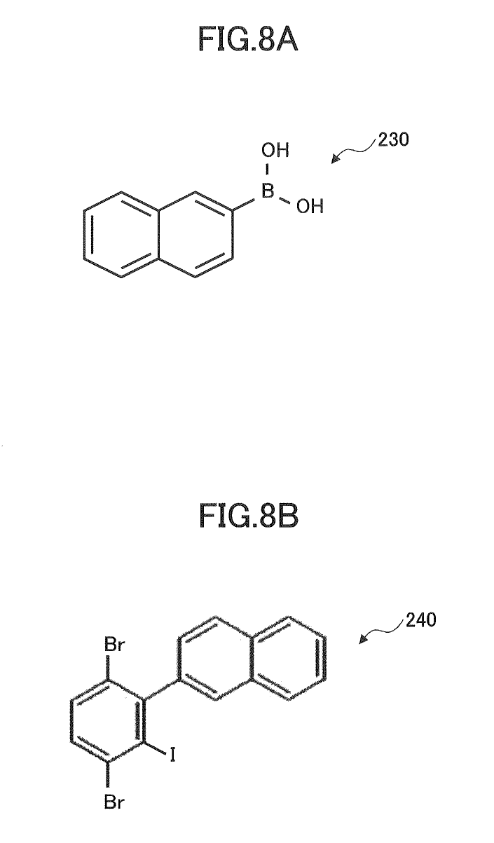

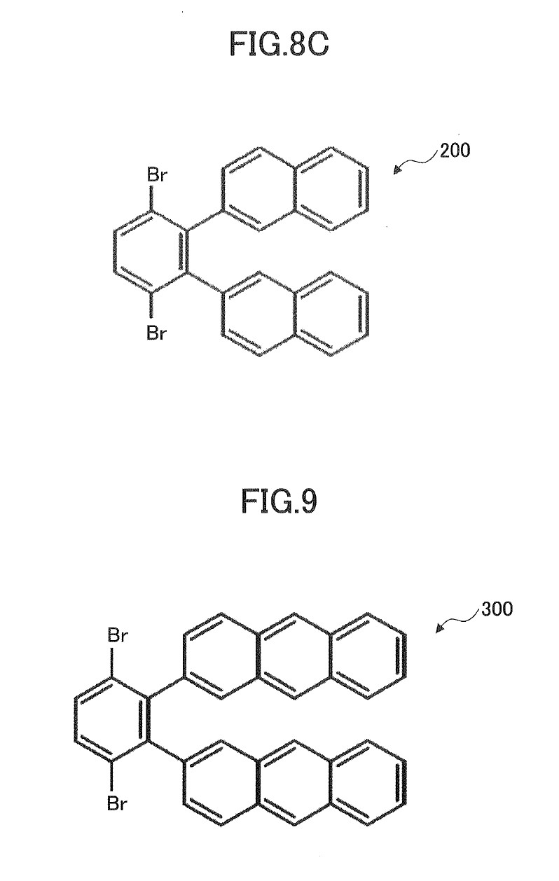

Next, a method of producing the GNR precursor 200 according to the second embodiment will be described. FIG. 8A to FIG. 8C are diagrams illustrating a method of producing the GNR precursor 200 according to the second embodiment.

First, 1,4-dibromo-2,3-diiodobenzene, which is indicated by a structural formula in which X is Br in FIG. 4A, and 2-naphthylboronic acid 230, which is indicated by a structural formula of FIG. 8A, are prepared.

Next, these are dissolved in a solvent, a catalyst is added and stirred in the presence of a base to cause a Suzuki coupling reaction. By continuing stirring to evaporate the solvent, as illustrated in FIG. 8B, a substance 240 having a bond at a location of one iodine (I) contained in 1,4-dibromo-2,3-diiodobenzene is obtained.

Subsequently, the substance 240, which is illustrated in FIG. 8B, and 2-naphthaleneboronic acid 230 are dissolved in a solvent, a catalyst is added and stirred in the presence of a base to cause a Suzuki coupling reaction. By continuing stirring to evaporate the solvent, as illustrated in FIG. 8C, the GNR precursor 200 having a bond at a location of one iodine (I) contained in the substance 240 is obtained.

Then, purification of the GNR precursor 200 is carried out, for example, by column chromatography.

In this way, the GNR precursor 200 can be produced.

For example, the solvent is dioxane (C₄H₈O₂), the catalyst is tetrakis (triphenylphosphine) palladium (Pd(PPh₃)₄), the base is sodium hydroxide (NaOH), and the temperature of the solution during stirring is in a range of 80° C. to 100° C.

### Third Embodiment

Next, a third embodiment will be described. The third embodiment relates to a GNR and a GNR precursor that is suitable for producing the GNR. FIG. 9 is a diagram illustrating a structural formula of a GNR precursor 300 according to the third embodiment.

The GNR precursor 300 according to the third embodiment has a structure illustrated in FIG. 9. That is, the GNR precursor 300 according to the third embodiment has the structure indicated by a structural formula in which n₁ is 3, X is Br, and Y and Z are H in FIG. 1. The desorption temperature of Br from the carbon atoms constituting a six-membered ring is lower than the desorption temperature of H from the carbon atoms constituting a six-membered ring. The GNR precursor 300 is 1,2-bis-(2-anthracenyl)-3,6-dibromobenzene.

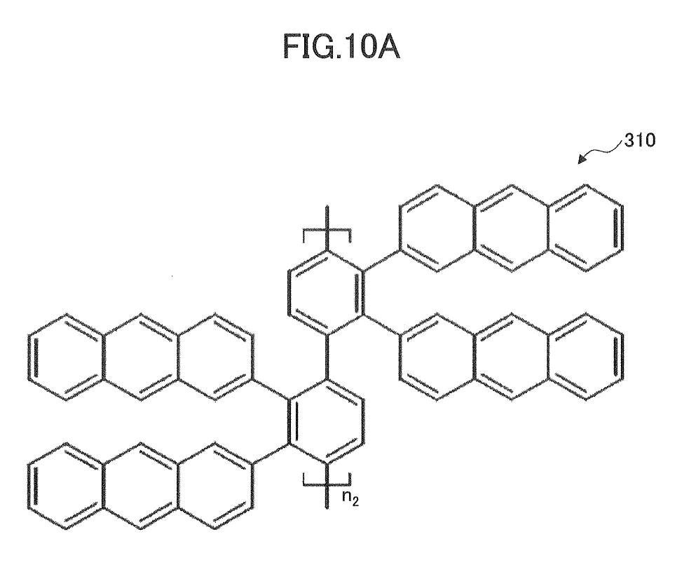

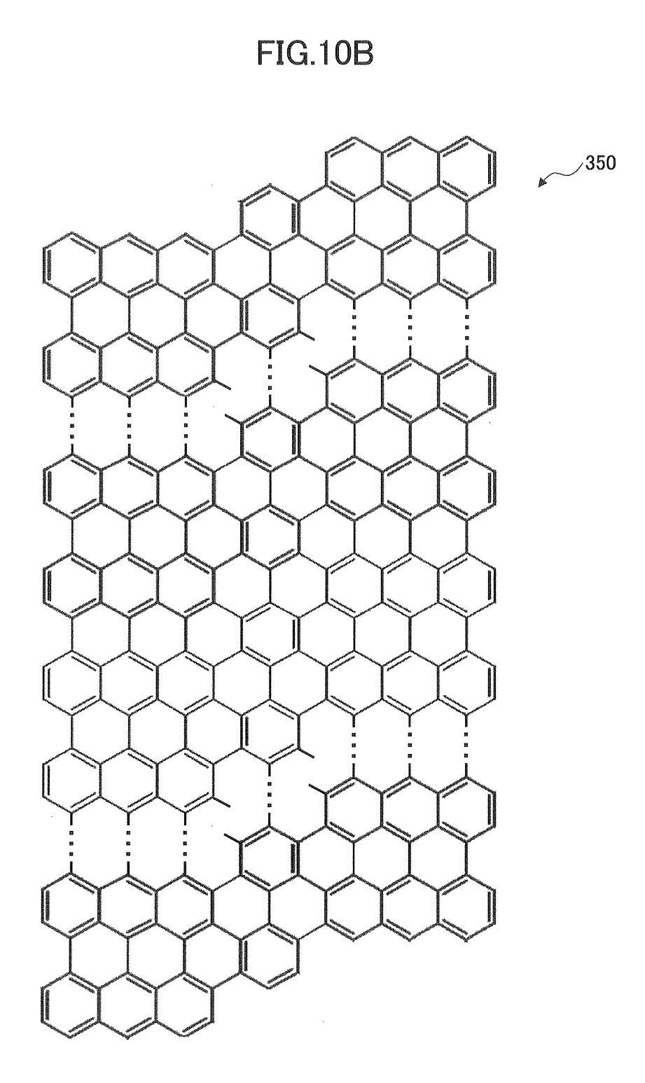

Here, a method of producing a GNR using the GNR precursors 300 according to the third embodiment will be described. FIG. 10A and FIG. 10B are diagrams illustrating a method of producing a GNR using the GNR precursors 300 according to the third embodiment. In this method a 17-AGNR is produced in situ.

First, similarly to the second embodiment, a surface cleaning process of a substrate on which a GNR is grown is performed. By the surface cleaning process, organic contaminants on the surface of the substrate can be removed and the surface flatness can be enhanced.

Next, without exposing the substrate, on which the surface cleaning treatment has been performed, to the atmosphere, under ultra-high vacuum, the temperature of the substrate is held at a first temperature, which is greater than or equal to the desorption temperature of Br and less than the desorption temperature of H, to heat and sublimate the GNR precursors 300. For example, the base pressure in a vacuum chamber is set to less than or equal to 5×10⁻⁸ Pa and the temperature of the substrate is set in a range of 150° C. to 250° C.; additionally, a K-cell type evaporator is used to heat and sublimate the GNR precursors 300, and the heating temperature of the GNR precursors 300 is set to approximately 100° C.

De-Br reaction and C—C bonding reaction of the GNR precursors 300 are induced on the substrate at the first temperature, and as illustrated in FIG. 10A, a polymer 310, in which a plurality of molecules of the GNR precursors 300 are arranged in one direction while turning back the direction of protrusion, is stably formed. For example, at this time, the deposition rate is in a range of 0.01 nm/min to 0.05 nm/min, and the vapor deposition thickness is in a range of 0.5 ML to 1 ML.

Subsequently, the temperature of the substrate is heated to a second temperature, which is greater than or equal to the desorption temperature of H, and is held at the second temperature. As a result, de-H reaction and cyclization reaction are induced, and as illustrated in FIG. 10B, a 17-AGNR 350 whose edge structure is of armchair type is formed from the polymer 310. For example, the second temperature is set in a range of 350° C. to 450° C., the heating rate from the first temperature to the second temperature is set in a range of 1° C./min to 5° C./min, and the holding time at the second temperature is set in a range of 10 minutes to 1 hour.

In this way, upon heating the GNR precursors 300, Br's are detached and C's, from which Br's are detached, are bonded with each other between the GNR precursors 300. Thereafter, H's are detached, and C's, from which H's are detached, are bonded with each other between the GNR precursors 300. A sequence (array) of the GNR precursors 300 is determined by bonding C's, to which Br's have been bonded, with each other, and thereafter, a structure of the 17-AGNR 350 is fixed by bonding C's, to which H's have been bonded, with each other. Therefore, it is possible to stably synthesize a long 17-AGNR 350. For example, it is possible to stably synthesize a 17-AGNR 350 on an order of several tens of nm. Therefore, by using the GNR precursors 300 according to the third embodiment, a long 17-AGNR 350 can be produced by a bottom-up method.

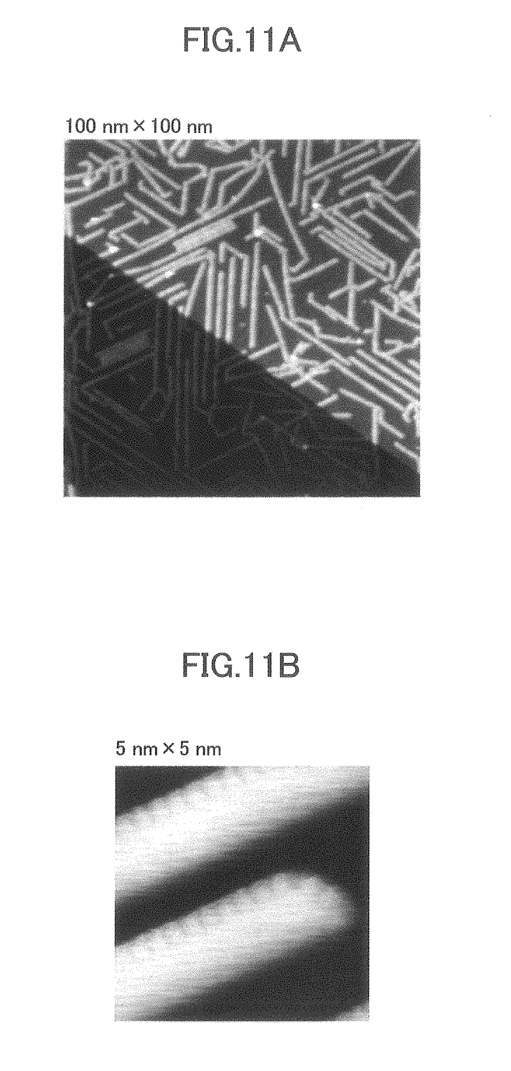

FIG. 11A and FIG. 11B illustrate topographic images of a 17-AGNR, produced according to the third embodiment, taken by a STM. The scan area in FIG. 11A is 100 nm×100 nm, and in this picture, a sample bias Vₛ is set to −1.0 V and a tunnel current Iₜ is set to 50 pA. The scan area in FIG. 11B is 5 nm×5 nm, and in this picture, a sample bias Vₛ is set to 1.2 V and a tunnel current Iₜ is set to 0.81 nA. The 17-AGNR is synthesized on an Au (111) substrate, and as illustrated in FIG. 11A and FIG. 11B, the 17-AGNR with a ribbon length in a range of 20 nm to 50 nm can be synthesized. According to first principles simulation considering many-body effects, the band gap E_{g} of the 17-AGNR is estimated to be 0.62 eV.

As the substrate, a substrate similar to that in the second embodiment can be used.

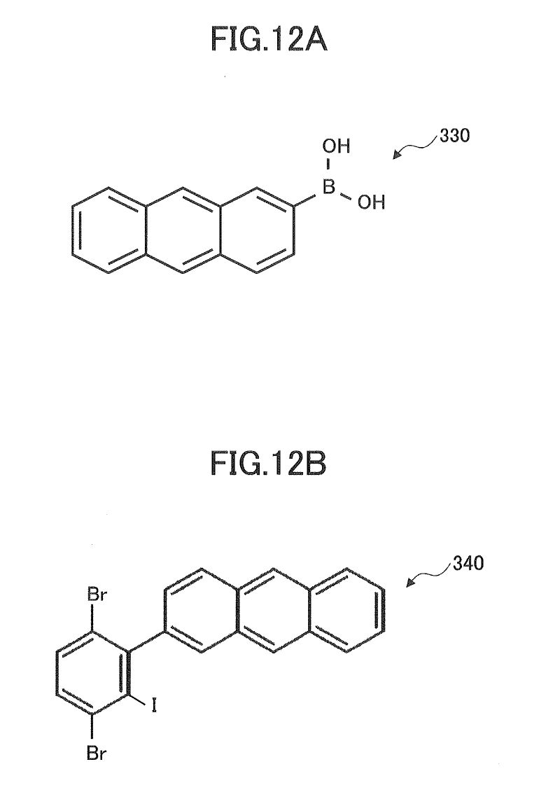

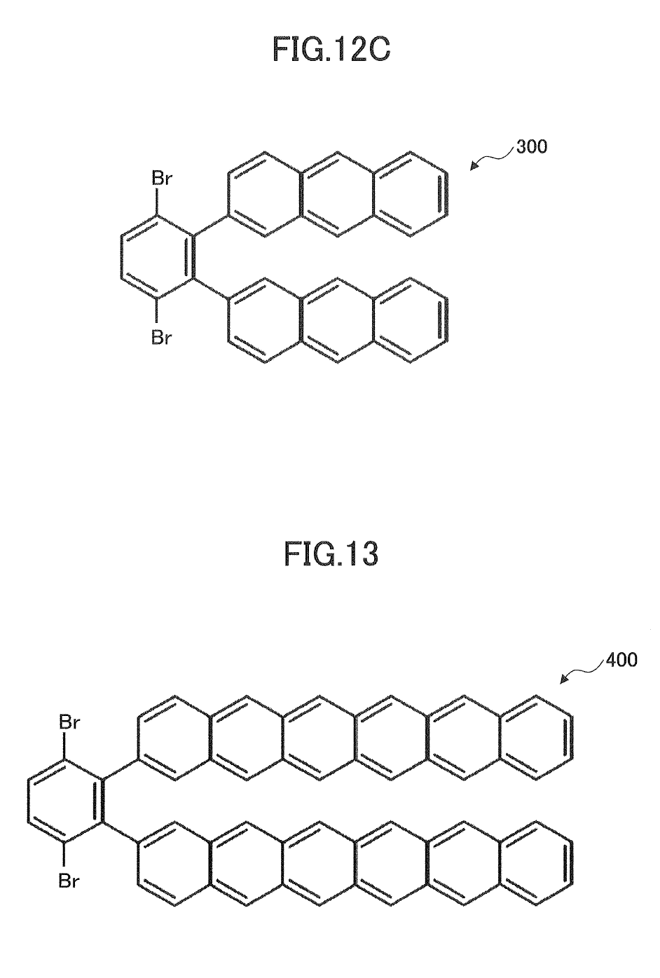

Next, a method of producing the GNR precursor 300 according to the third embodiment will be described. FIG. 12A to FIG. 12C are diagrams illustrating a method of producing the GNR precursor 300 according to the third embodiment.

First, 1,4-dibromo-2,3-diiodobenzene, which is indicated by a structural formula in which X is Br in FIG. 4A, and 2-anthraceneboronic acid 330, which is indicated by a structural formula of FIG. 12A, are prepared.

Next, these are dissolved in a solvent, a catalyst is added and stirred in the presence of a base to cause a Suzuki coupling reaction. By continuing stirring to evaporate the solvent, as illustrated in FIG. 12B, a substance 340 having a bond at a location of one iodine (I) contained in 1,4-dibromo-2,3-diiodobenzene is obtained.

Subsequently, the substance 340, which is illustrated in FIG. 12B, and 2-anthraceneboronic acid 330 are dissolved in a solvent, a catalyst is added and stirred in the presence of a base to cause a Suzuki coupling reaction. By continuing stirring to evaporate the solvent, as illustrated in FIG. 12C, the GNR precursor 300 having a bond at a location of one iodine (I) contained in the substance 340 is obtained.

Then, purification of the GNR precursor 300 is carried out, for example, by column chromatography.

In this way, the GNR precursor 300 can be produced.

For example, the solvent is dioxane (C₄H₈O₂), the catalyst is tetrakis (triphenylphosphine) palladium (Pd(PPh₃)₄), the base is sodium hydroxide (NaOH), and the temperature of the solution during stirring is in a range of 80° C. to 100° C.

### Fourth Embodiment

Next, a fourth embodiment will be described. The fourth embodiment relates to a GNR and a GNR precursor that is suitable for producing the GNR. FIG. 13 is a diagram illustrating a structural formula of a GNR precursor 400 according to the fourth embodiment.

The GNR precursor 400 according to the fourth embodiment has a structure illustrated in FIG. 13. That is, the GNR precursor 400 according to the fourth embodiment has the structure indicated by a structural formula in which n₁ is 6, X is Br, and Y and Z are H in FIG. 1. The desorption temperature of Br from the carbon atoms constituting a six-membered ring is lower than the desorption temperature of H from the carbon atoms constituting a six-membered ring. The GNR precursor 400 is 1,2-bis-(2-hexacenyl)-3,6-dibromobenzene.

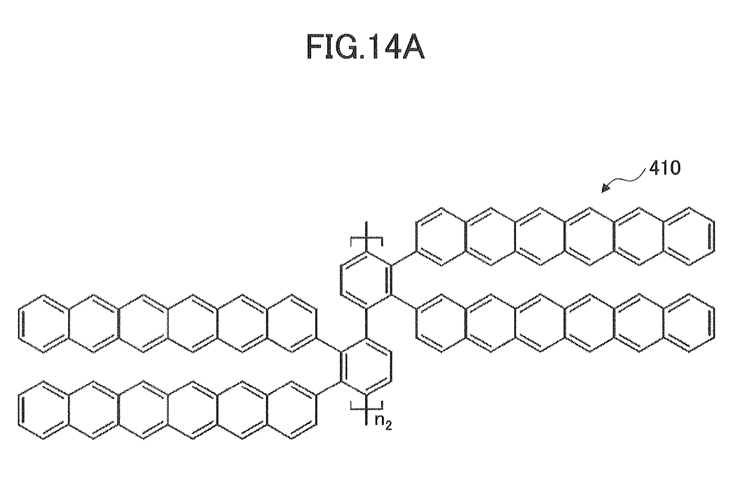

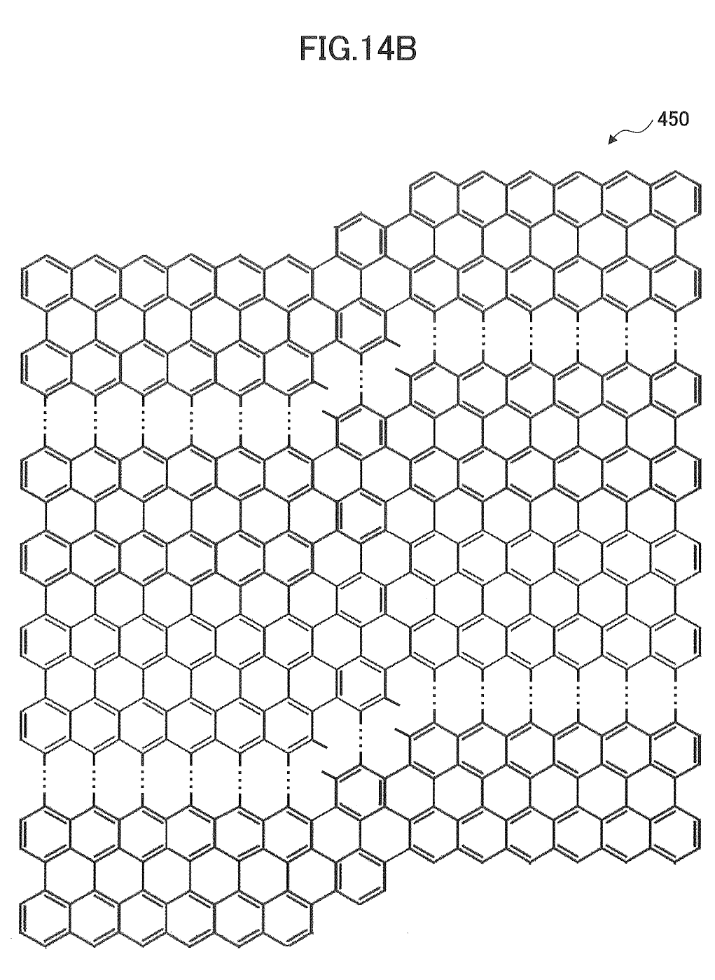

Here, a method of producing a GNR using the GNR precursors 400 according to the fourth embodiment will be described. FIG. 14A and FIG. 14B are diagrams illustrating a method of producing a GNR using the GNR precursors 400 according to the fourth embodiment. In this method a 29-AGNR is produced in situ.

First, similarly to the second embodiment, a surface cleaning process of a substrate on which a GNR is grown is performed. By the surface cleaning process, organic contaminants on the surface of the substrate can be removed and the surface flatness can be enhanced.

Next, without exposing the substrate, on which the surface cleaning treatment has been performed, to the atmosphere, under ultra-high vacuum, the temperature of the substrate is held at a first temperature, which is greater than or equal to the desorption temperature of Br and less than the desorption temperature of H, to heat and sublimate the GNR precursors 400. For example, the base pressure in a vacuum chamber is set to less than or equal to 5×10⁻⁸ Pa and the temperature of the substrate is set in a range of 150° C. to 250° C.; additionally, a K-cell type evaporator is used to heat and sublimate the GNR precursors 400, and the heating temperature of the GNR precursors 400 is set to approximately 250° C.

De-Br reaction and C—C bonding reaction of the GNR precursors 400 are induced on the substrate at the first temperature, and as illustrated in FIG. 14A, a polymer 410, in which a plurality of molecules of the GNR precursors 400 are arranged in one direction while turning back the direction of protrusion, is stably formed. For example, at this time, the deposition rate is in a range of 0.01 nm/min to 0.05 nm/min, and the vapor deposition thickness is in a range of 0.5 ML to 1 ML.

Subsequently, the temperature of the substrate is heated to a second temperature, which is greater than or equal to the desorption temperature of H, and is held at the second temperature. As a result, de-H reaction and cyclization reaction are induced, and as illustrated in FIG. 14B, a 29-AGNR 450 whose edge structure is of armchair type is formed from the polymer 410. For example, the second temperature is set in a range of 350° C. to 450° C., the heating rate from the first temperature to the second temperature is set in a range of 1° C./min to 5° C./min, and the holding time at the second temperature is set in a range of 10 minutes to 1 hour.

In this way, upon heating the GNR precursors 400, Br's are detached and C's, from which Br's are detached, are bonded with each other between the GNR precursors 400. Thereafter, H's are detached, and C's, from which H's are detached, are bonded with each other between the GNR precursors 400. A sequence (array) of the GNR precursors 400 is determined by bonding C's, to which Br's have been bonded, with each other, and thereafter, a structure of the 29-AGNR 450 is fixed by bonding C's, to which H's have been bonded, with each other. Therefore, it is possible to stably synthesize a long 29-AGNR 450. For example, it is possible to stably synthesize a 29-AGNR 450 on an order of several tens of nm. Therefore, by using the GNR precursors 400 according to the fourth embodiment, a long 29-AGNR 450 can be produced by a bottom-up method.

As the substrate, a substrate similar to that in the second embodiment can be used.

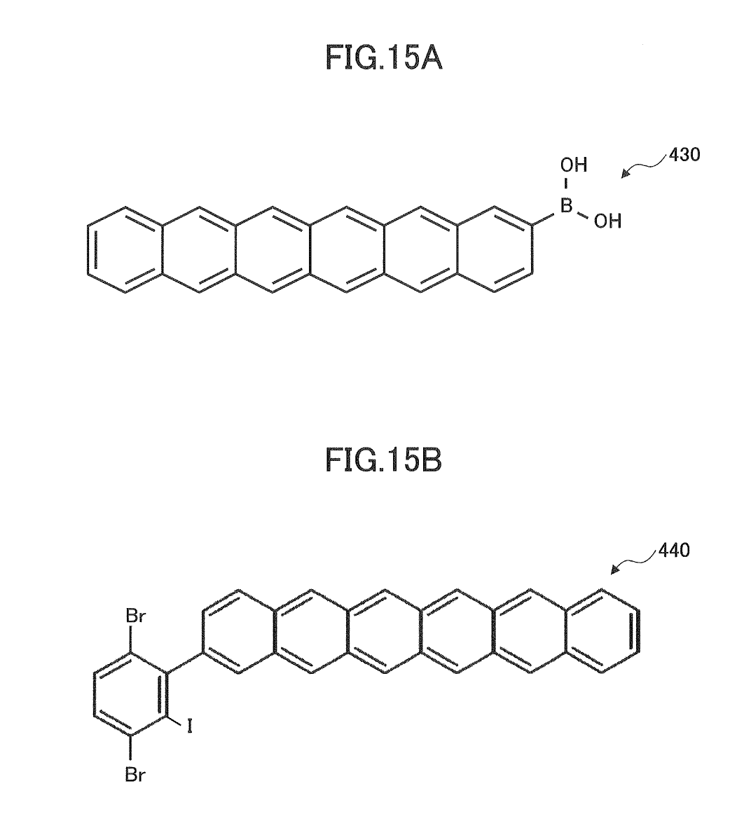

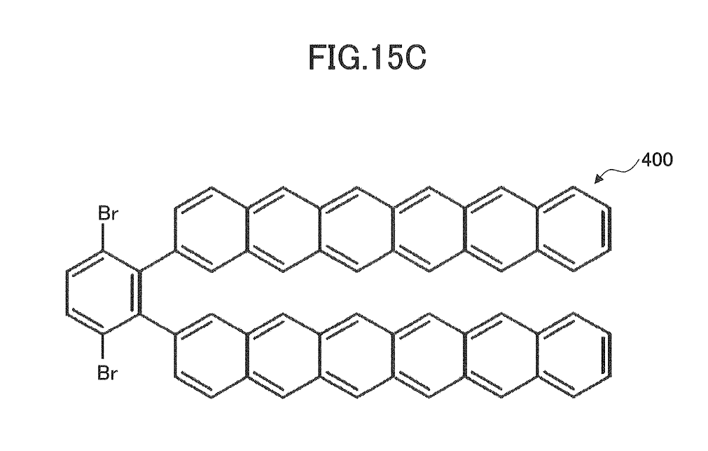

Next, a method of producing the GNR precursor 400 according to the fourth embodiment will be described. FIG. 15A to FIG. 15C are diagrams illustrating a method of producing the GNR precursor 400 according to the fourth embodiment.

First, 1,4-dibromo-2,3-diiodobenzene, which is indicated by a structural formula in which X is Br in FIG. 4A, and 2-hexaceneboronic acid 430, which is indicated by a structural formula of FIG. 15A, are prepared.

Next, these are dissolved in a solvent, a catalyst is added and stirred in the presence of a base to cause a Suzuki coupling reaction. By continuing stirring to evaporate the solvent, as illustrated in FIG. 15B, a substance 440 having a bond at a location of one iodine (I) contained in 1,4-dibromo-2,3-diiodobenzene is obtained.

Subsequently, the substance 440, which is illustrated in FIG. 15B, and 2-hexaceneboronic acid 430 are dissolved in a solvent, a catalyst is added and stirred in the presence of a base to cause a Suzuki coupling reaction. By continuing stirring to evaporate the solvent, as illustrated in FIG. 15C, the GNR precursor 400 having a bond at a location of one iodine (I) contained in the substance 440 is obtained.

Then, purification of the GNR precursor 400 is carried out, for example, by column chromatography.

In this way, the GNR precursor 400 can be produced.

For example, the solvent is dioxane (C₄H₈O₂), the catalyst is tetrakis (triphenylphosphine) palladium (Pd(PPh₃)₄), the base is sodium hydroxide (NaOH), and the temperature of the solution during stirring is in a range of 80° C. to 100° C.

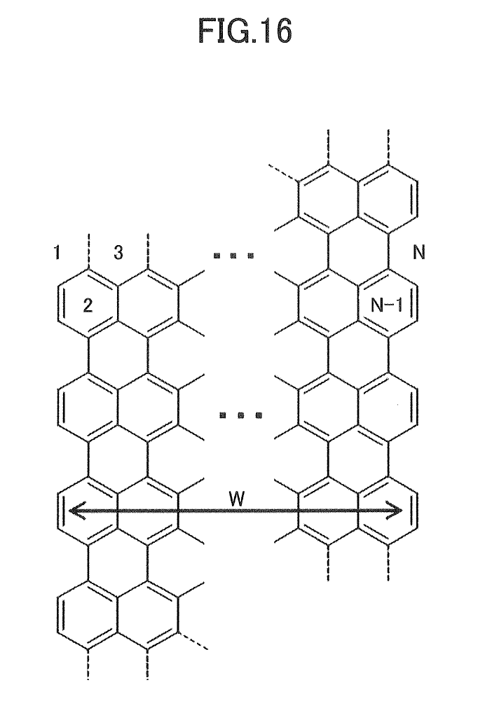

Table 1 indicates a relationship between the value of n₁ of AGNR, the number N of C—C dimer lines in the ribbon width direction, the subfamily, the ribbon width W, and the band gap E_{g}. The bandgaps E_{g} are values calculated from first principles simulation in consideration of the many-body effects. In this calculation, all the edge modified groups of AGNRs are H. FIG. 16 illustrates a relationship between C—C dimer lines and the ribbon width W.

TABLE 1

| n₁ | N | SUBFAMILY | W (nm) | E_{g} (eV) |
|---|---|---|---|---|
| 1 | 9 | 3p | 0.98 | 2.07 |
| 2 | 13 | 3p + 1 | 1.48 | 2.34 |
| 3 | 17 | 3p + 2 | 1.97 | 0.62 |
| 4 | 21 | 3p | 2.46 | 1.05 |
| 5 | 25 | 3p + 1 | 2.95 | 1.32 |
| 6 | 29 | 3p + 2 | 3.44 | 0.38 |

As indicated in Table 1, by the number (n₁) of six-membered rings modified (attached) on C positions 1 and 2 of the six-membered ring containing modified (attached) groups X, the ribbon width of the N-AGNR can be systematically controlled to realize bandgap engineering.

### Fifth Embodiment

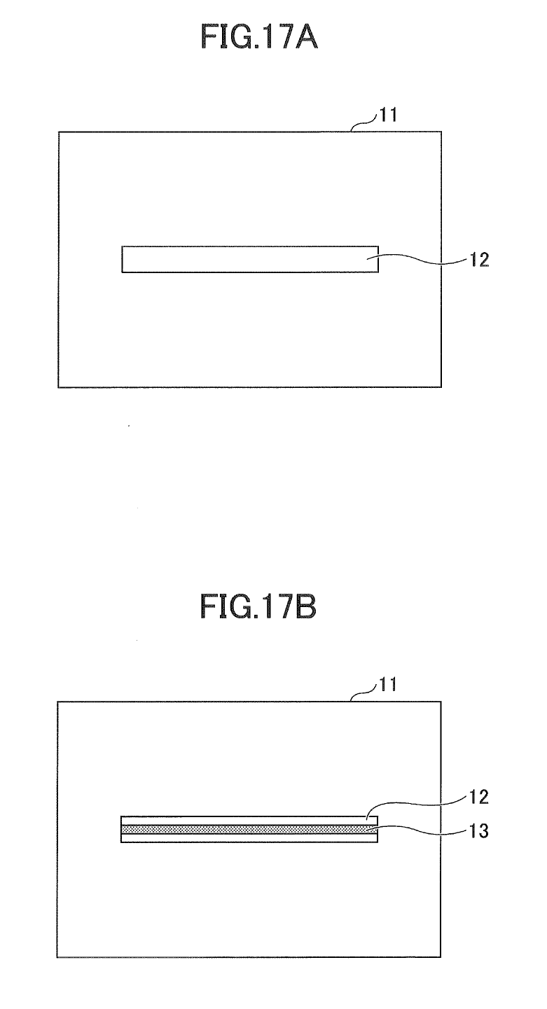

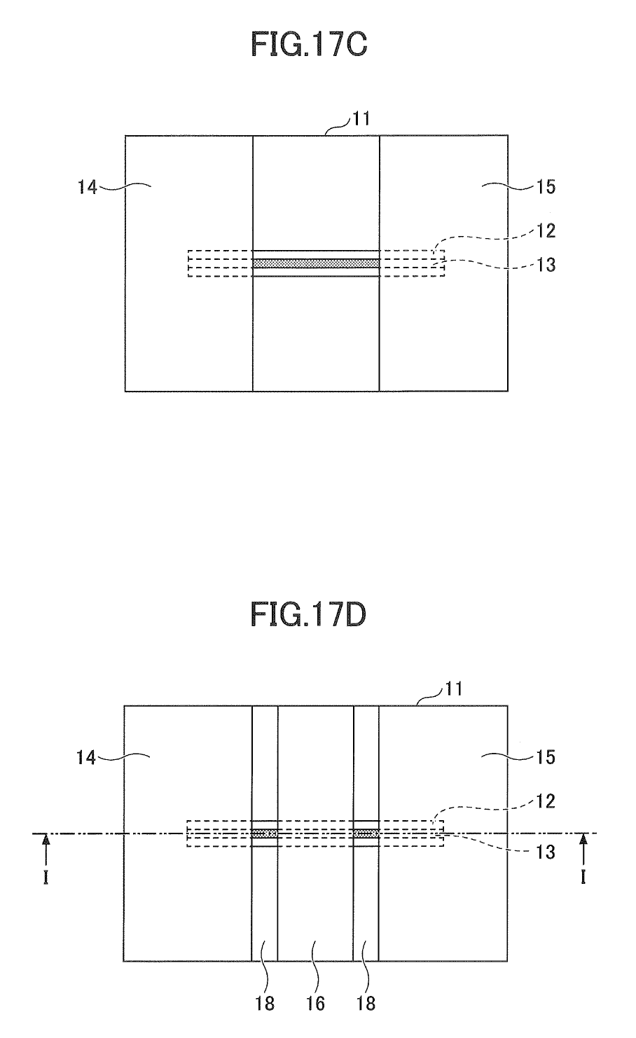

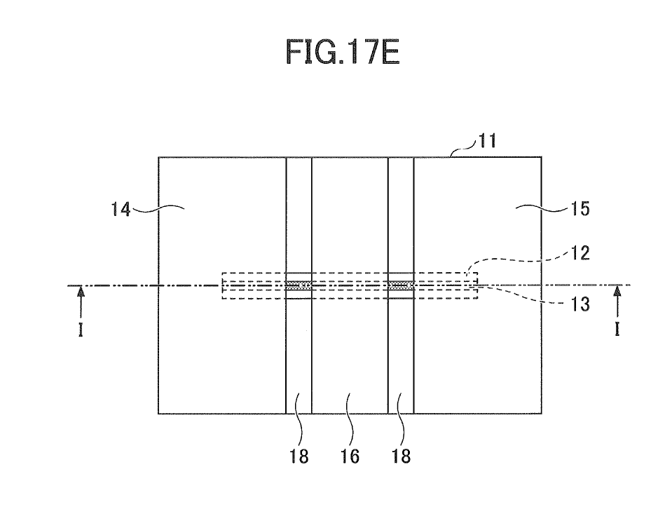

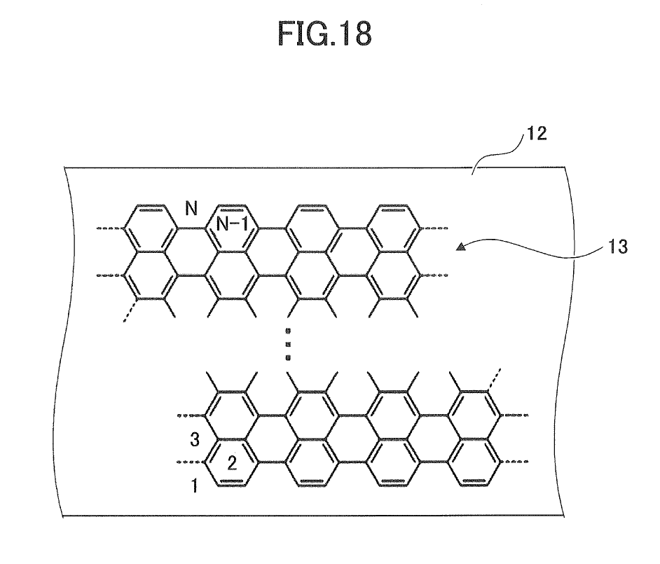

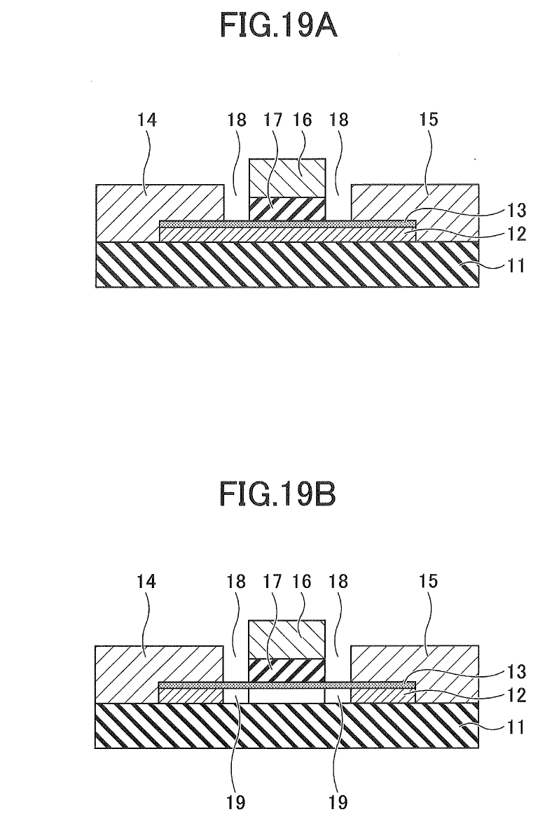

Next, a fifth embodiment will be described. The fifth embodiment relates to an electronic device including a field effect transistor (FET) using an N-AGNR as a channel and a producing method thereof. FIG. 17A to FIG. 17E are top views illustrating a method of producing an electronic device according to the fifth embodiment in the order of steps. FIG. 18 is a diagram illustrating a positional relationship between a metal pattern and an N-AGNR according to the fifth embodiment. FIG. 19A and FIG. 19B are cross-sectional views illustrating the method of producing the electronic device according to the fifth embodiment in the order of steps.

First, as illustrated in FIG. 17A, a metal layer is deposited on an insulating substrate 11, and a metal pattern 12 is formed by patterning the metal layer by electron beam lithography and dry etching. For example, the insulating substrate 11 is a mica substrate cleaved to expose a clean surface, and the metal layer is an Au layer having a thickness in a range of 10 nm to 50 nm. The Au layer can be deposited on the cleaved surface of the mica substrate by vapor deposition. By depositing the Au layer while heating the mica substrate to a temperature in a range of 400° C. to 550° C., the surface of the Au layer can be oriented in the (111) plane. Cu, Ni, Rh, Pd, Ag, Ir or Pt may be used as a material of the metal layer. Depending on the type of a substrate, it is possible to control the epitaxial crystal plane of the metal layer.

A polymerization reaction and a cyclization reaction of GNR precursors are not induced on the surface of the insulating substrate 11. Therefore, the position and the size of the N-AGNR can be controlled based on the position and the size of the metal pattern 12. For example, the dimension (length) in the longitudinal direction of the metal pattern 12 is adjusted in consideration of the channel length of the FET to be produced, and the dimension (width) in the short direction is adjusted in consideration of the band gap (ribbon width) of the N-AGNR used for the FET. For example, the length of the metal pattern 12 is in a range of 50 nm to 500 nm, and the width of the metal pattern 12 is in a range of 1 nm to 5 nm.

In the patterning of the metal layer, an electron beam resist is spin-coated on the metal layer, and a mask pattern for etching the metal layer is formed on the electron beam resist. As the electron beam resist, a resist obtained by diluting ZEP 520A (manufactured by Zeon Corporation) with ZEP-A (manufactured by Zeon Corporation) at a ratio of 1: 1 can be used. Then, using the mask pattern, an etching process of the metal layer is performed by Ar ion milling. In this manner, the metal pattern 12 can be formed.

Next, as illustrated in FIG. 17B, an N-AGNR 13 is formed on the metal pattern 12. The N-AGNR 13 can be formed by using the GNR precursors 100 according to the first embodiment. As a preprocess for forming the N-AGNR 13, a surface cleaning process of the metal pattern 12 is performed. By this surface cleaning process, organic contaminants such as a resist residue attached on the surface of the metal pattern 12 can be removed, and the flatness of the (111) surface of the Au layer can be enhanced. The N-AGNR 13 is formed in situ in a vacuum chamber of an ultra-high vacuum without exposing, to the atmosphere, the metal pattern 12 on which the surface cleaning process has been performed.

For example, while maintaining the temperature of the insulating substrate 11 and the metal pattern 12 in a range of 150° C. to 250° C., the GNR precursors 100 are vapor-deposited on the surface of the metal pattern 12. Thereafter, the temperature of the insulating substrate 11 and the metal pattern 12 is heated to in a range of 350° C. to 450° C. As a result, polymerization reaction, de-H reaction, and cyclization reaction of the GNR precursors 100 are induced, and the N-AGNR 13 whose position and size are controlled by the metal pattern 12 is formed. That is, as illustrated in FIG. 18, the N-AGNR 13 is formed in a self-organized manner so as to extend along the longitudinal direction of the metal pattern 12.

Subsequently, as illustrated in FIG. 17C, by electron beam lithography, vapor deposition, and lift-off, a source electrode 14 is formed on one end portion of the N-AGNR 13 and a drain electrode 15 is formed on the other end portion of the N-AGNR 13. The source electrode 14 and the drain electrode 15 are, for example, a two-layer electrode including a Ti film and a Cr film on the Ti film.

In forming the source electrode 14 and the drain electrode 15, a two-layer resist is spin-coated on the N-AGNR 13, the metal pattern 12 and the insulating substrate 11, and an electrode pattern is formed on the two-layer resist by electron beam lithography. For example, a diluted resist of ZEP 520A is used as the upper layer of the two-layer resist, and PMGI SFG2S (manufactured by Michrochem Corporation) is used as the lower layer, which is a sacrificial layer, of the two-layer resist. After the electrode pattern is formed, a Ti film having a thickness in a range of 0.5 nm to 1 nm and a Cr film having a thickness in a range of 30 nm to 50 nm are deposited by vapor deposition. Subsequently, lift-off is performed by removing the two-layer resist. In this way, the source electrode 14 and the drain electrode 15 are formed.

Next, as illustrated in FIGS. 17D and 19A, by electron beam lithography, vapor deposition, and lift-off, a gate stack structure of a gate electrode 16 and a gate insulating layer 17 is formed on the N-AGNR 13. This gate stack structure is formed such that opening portions 18 are formed between the source electrode 14 and the drain electrode 15. For example, the gate length is in a range of 8 nm to 12 nm, the gate insulating layer 17 is a Y₂O₃ layer, and the gate electrode 16 is a two-layer electrode including a Ti film and a Cr film on the Ti film. In forming the gate electrode 16 and the gate insulating layer 17, similarly to the formation of the source electrode 14 and the drain electrode 15, a two-layer resist is spin-coated and a gate pattern is formed on the two-layer resist by electron beam lithography. For example, a diluted resist of ZEP 520A is used as the upper layer of the two-layer resist, and PMGI SFG2S is used as the lower layer, which is a sacrificial layer, of the two-layer resist. After the gate pattern is formed, a Y₂O₃ layer having a thickness in a range of 5 nm to 10 nm, a Ti film having a thickness in a range of 0.5 nm to 1 nm, and a Cr film having a thickness in a range of 30 nm to 50 nm are deposited by vapor deposition. Subsequently, lift-off is performed by removing the two-layer resist. In this way, the gate stack structure of the gate electrode 16 and the gate insulating layer 17 is formed. The Y₂O₃ layer can be formed by vapor-depositing Y metal while introducing O₂ gas into a vacuum chamber. As a material of the gate insulating layer 17, SiO₂, HfO₂, ZrO₂, La₂O, or TiO₂ may be used. Also in a case of using such a material, the gate insulating layer 17 can be formed by vapor-depositing metal while introducing O₂ gas into a vacuum chamber.

Thereafter, as illustrated in FIG. 17E and FIG. 19B, portions of the metal pattern 12 that are not covered with the source electrode 14 or the drain electrode 15 are removed by wet etching to form voids 19. In a case where Au is used for the metal pattern, a KI aqueous solution can be used as an etchant. Because the source electrode 14, the drain electrode 15, and the gate electrode 16 are two-layer electrodes including a Ti film and a Cr film, the source electrode 14, the drain electrode 15, and the gate electrode 16 have excellent etching resistance to the KI aqueous solution. After the wet etching of the metal pattern 12, washing with pure water and a rinse process with isopropyl alcohol are performed in this order. Subsequently, as a drying process, for example, a supercritical drying process using CO₂ gas is performed. The supercritical drying process using CO₂ gas is suitable for preventing N-AGNR 13 from being cut due to a surface tension or a capillary force of the solution.

In this way, it is possible to produce an electronic device including an FET having, as a channel, the N-AGNR 13 suspended by (connected with) the source electrode 14, the drain electrode 15, and the gate insulating layer 17. This electronic device can operate with graphene-specific high mobility carriers.

### Sixth Embodiment

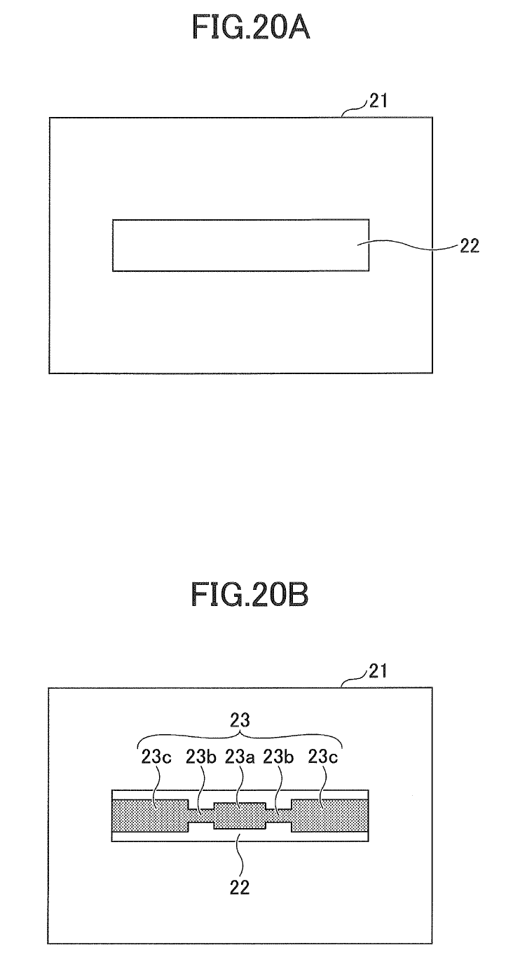

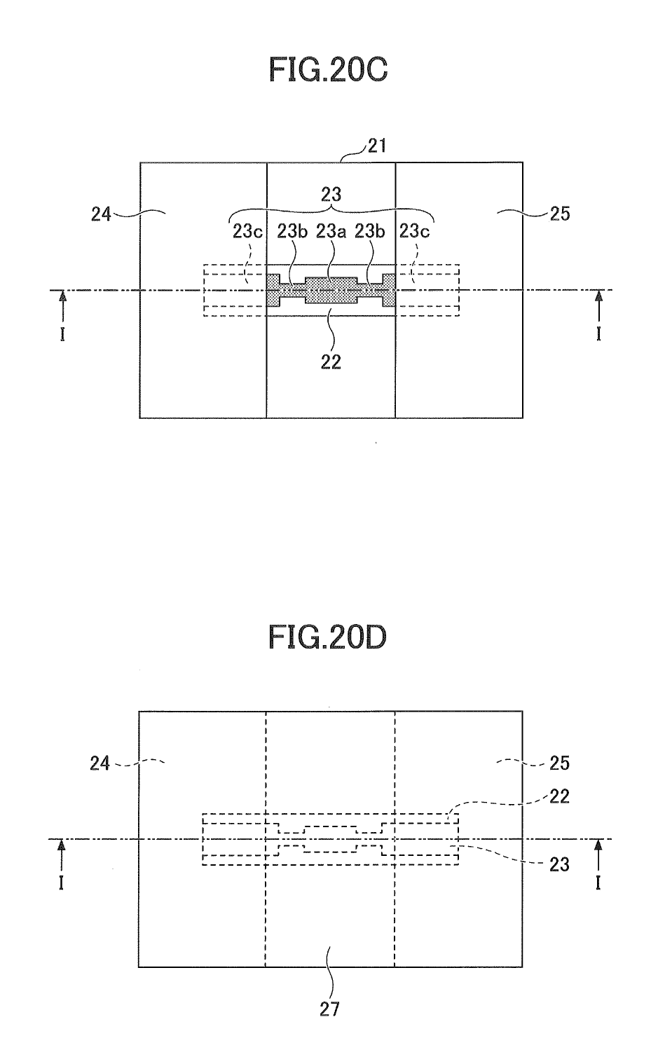

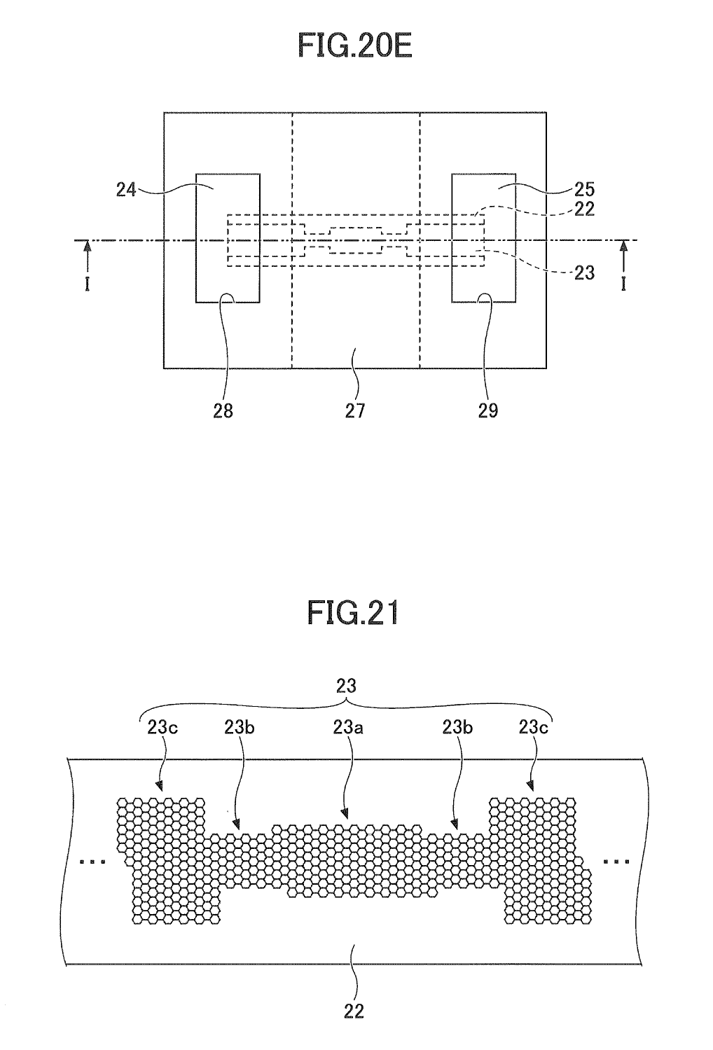

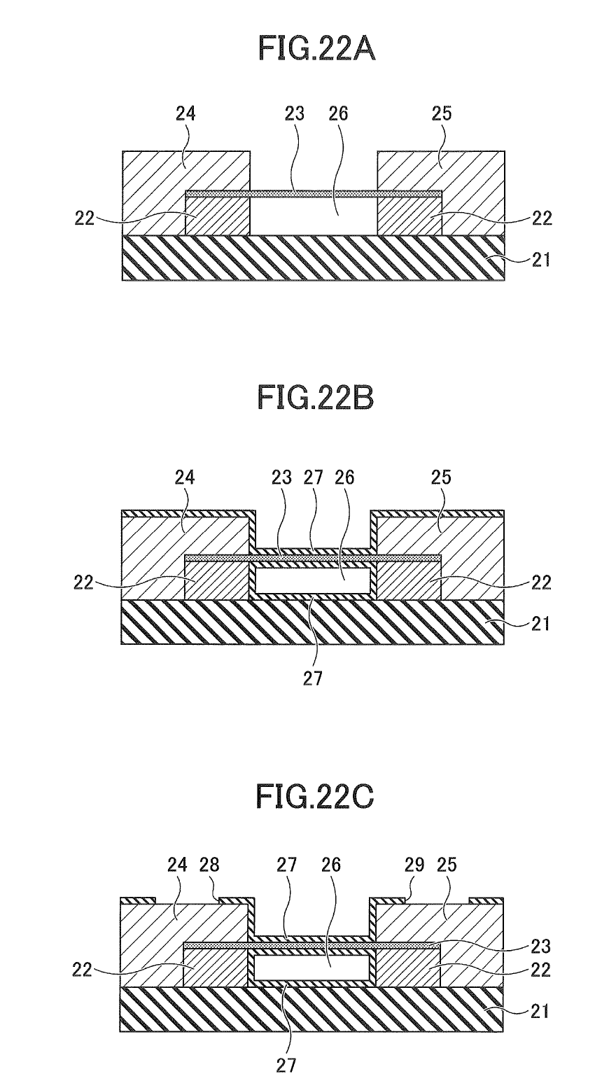

Next, a sixth embodiment will be described. The sixth embodiment relates to an electronic device including a resonant tunneling diode (RTD) using a heterojunction AGNR and a producing method thereof. The heterojunction AGNR is an example of an AGNR. FIG. 20A to FIG. 20E are top views illustrating a method of producing an electronic device according to the sixth embodiment in the order of steps. FIG. 21 is a diagram illustrating a positional relationship between a metal pattern and an N-AGNR according to the sixth embodiment. FIG. 22A to FIG. 22C are cross-sectional views illustrating the method of producing the electronic device according to the sixth embodiment in the order of steps.

First, as illustrated in FIG. 20A, a metal layer is deposited on an insulating substrate 21, and a metal pattern 22 is formed by patterning the metal layer by electron beam lithography and dry etching. For example, the insulating substrate 21 is a mica substrate cleaved to expose a clean surface, and the metal layer is an Au layer having a thickness in a range of 10 nm to 50 nm. As materials of the insulating substrate 21 and the metal pattern 22, materials similar to those of the insulating substrate 11 and the metal pattern 12 can be used. For example, the dimension (length) in the longitudinal direction of the metal pattern 22 is adjusted in consideration of the length of the RTD to be produced, and the dimension (width) in the short direction is adjusted in consideration of the band gap (ribbon width) of the heterojunction AGNR used for the RTD. For example, the length of the metal pattern 22 is in a range of 40 nm to 60 nm, and the width of the metal pattern 22 is in a range of 4 nm to 6 nm.

Next, as illustrated in FIG. 20B, the heterojunction AGNR 23 is formed on the metal pattern 22. The heterojunction AGNR 23 can be formed by using the GNR precursors 200 according to the second embodiment, the GNR precursors 300 according to the third embodiment, and the GNR precursors 400 according to the fourth embodiment. As a preprocess for forming the heterojunction AGNR 23, a surface cleaning process of the metal pattern 22 is performed. By this surface cleaning process, organic contaminants such as a resist residue attached on the surface of the metal pattern 22 can be removed, and the flatness of the (111) surface of the Au layer can be enhanced. The heterojunction AGNR 23 is formed in situ in a vacuum chamber of an ultra-high vacuum without exposing, to the atmosphere, the metal pattern 22 on which the surface cleaning process has been performed.

For example, while maintaining the temperature of the insulating substrate 21 and the metal pattern 22 in a range of 150° C. to 250° C., the GNR precursors 300, the GNR precursors 200, and the GNR precursors 400 are vapor-deposited in this order on the surface of the metal pattern 22. By the vapor-deposition of the GNR precursors 300, the polymer 310, which is illustrated in FIG. 10A, is formed in a self-organized manner on the metal pattern 22. By the vapor-deposition of the GNR precursors 200, the polymer 210, which is illustrated in FIG. 6A, is formed in a self-organized manner on both ends in the longitudinal direction of the polymer 310. By the vapor-deposition of the GNR precursors 400, the polymer 410, which is illustrated in FIG. 14A, is formed in a self-organized manner on both ends in the longitudinal direction of the polymer 210. In this way, a polymer chain is formed on the metal pattern 22.

Thereafter, the temperature of the insulating substrate 21 and the metal pattern 22 is raised to 350° C. to 450° C. As a result, de-H reaction and cyclization reaction of the GNR precursors 300, the GNR precursors 200, and the GNR precursors 400 are induced, and the heterojunction AGNR whose position and size are controlled by the metal pattern 22 is formed. That is, as illustrated in FIG. 21, the heterojunction AGNR 23 is formed so as to extend along the longitudinal direction of the metal pattern 22. The heterojunction AGNR 23 includes a 17-AGNR area 23a, 13-AGNR areas 23b on both ends of the 17-AGNR area 23a, and 29-AGNR areas 23c on respective ends of the 13-AGNR areas 23b. The lengths of the 17-AGNR area 23a, the 13-AGNR areas 23b and the 29-AGNR areas 23c can be controlled by the amounts of vapor-deposition of the GNR precursors 300, the GNR precursors 200, and the GNR precursors 400.

Subsequently, as illustrated in FIG. 20C and FIG. 22A, by electron beam lithography, vapor deposition, and lift-off, an electrode 24 is formed on one 29-AGNR 23c and an electrode 25 is formed on the other 29-AGNR 23c. The electrode 24 and the electrode 25 are, for example, a two-layer electrode including a Ti film and a Cr film on the Ti film. The electrode 24 and the electrode 25 can be formed by a method similar to that of the source electrode 14 and the drain electrode 15.

Thereafter, a portion of the metal pattern 22 that is not covered with the electrode 24 or the electrode 25 is removed by wet etching to form a void 26. In a case where Au is used for the metal pattern, a KI aqueous solution can be used as an etchant. As a result, the heterojunction AGNR 23 is suspended by (connected with) the electrode 24 and the electrode 25.

Thereafter, as illustrated in FIG. 20D and FIG. 22B, a protective layer 27 is formed on the entire surface side of the insulating substrate 21. As the protective layer 27, for example, HfO₂ having a thickness in a range of 3 nm to 10 nm is formed by atomic layer deposition (ALD). In this case, for example, tetrakis (dimethylamino) hafnium and H₂O are used as a precursor of the protective layer 27, and the deposition temperature is set to in a range of 220° C. to 280° C. The protective layer 27 is suitable for preventing cutting of the heterojunction AGNR 23. Because ALD does not have directivity in the deposition direction, as illustrated in FIG. 20D, the protective layer 27 is formed to cover the entire exposed surface of the heterojunction AGNR 23 and to cover the inner wall surface of the void 26. The protective layer 27 protects the heterojunction AGNR 23 in this manner. A material of the protective layer 27 may have an insulating property. As a material of the protective layer 27, Al₂O₃, Si₃N₄, HfSiO, HfAlON, Y₂O₃, SrTiO₃, PbZrTiO₃, or BaTiO₃ may be used.

Subsequently, as illustrated in FIG. 20E and FIG. 22C, by electron beam lithography and dry etching, a contact hole 28, which exposes a part of the electrode 24, and a contact hole 29, which exposes a part of the electrode 25, are formed on the protective layer 27.

In this manner, an electronic device having an RTD using the heterojunction AGNR 23 can be produced.

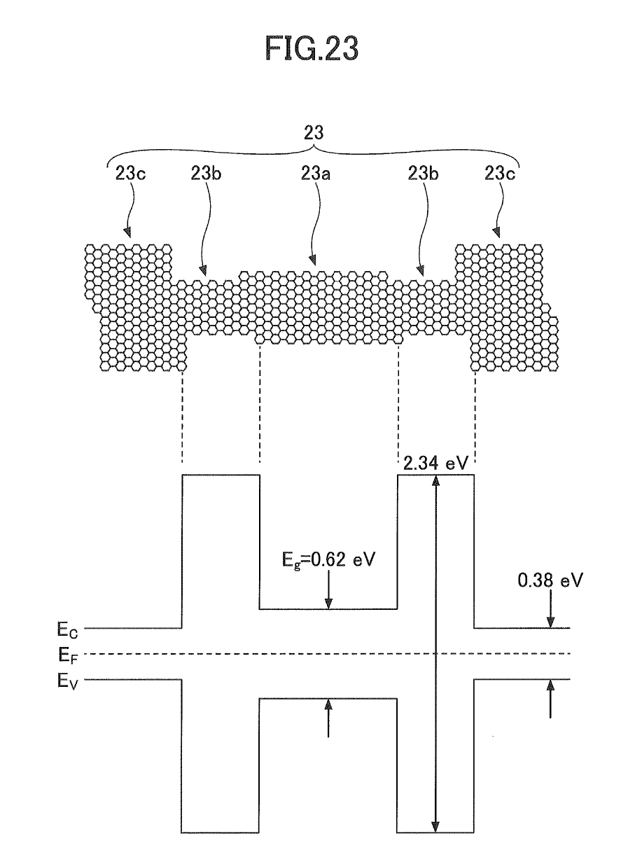

FIG. 23 illustrates a band structure of the heterojunction AGNR 23 of the electronic device according to the sixth embodiment, which is produced as described above. The band gap of the 17-AGNR area 23a is 0.62 eV, the band gap of the 13-AGNR areas 23b is 2.34 eV, and the band gap of the 29-AGNR areas 23c is 0.38 eV. Therefore, the heterojunction AGNR 23 can be suitably used for a RTD in which the 17-AGNR area 23a is a quantum well area and the 13-AGNR areas 23b are barrier areas. This electronic device can operate with graphene-specific high mobility carriers.

The GNR precursor 200, the GNR precursor 300 and the GNR precursor 400 have different values of n₁ but have a common basic backbone. Thus, the 17-AGNR area 23a, the 13-AGNR areas 23b, and the 29-AGNR areas 23c, which have different ribbon widths, are joined by sp² hybridized six-membered rings without causing junction defects in the ribbon length direction.

All examples and conditional language provided herein are intended for pedagogical purposes of aiding the reader in understanding the invention and the concepts contributed by the inventors to further the art, and are not to be construed as limitation to such specifically recited examples and conditions, nor does the organization of such examples in the specification relate to a showing of superiority and inferiority of the invention. Although one or more embodiments of the present invention have been described in detail, it should be understood that various changes, substitutions, and alterations could be made hereto without departing from the spirit and scope of the invention.

What is claimed is:

1. A graphene nanoribbon precursor having a structure that is indicated by a following chemical formula (1), 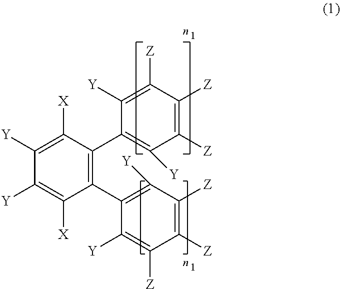
wherein in the above chemical formula (1),
n₁ is an integer that is greater than or equal to 1 and less than or equal to 6;
X, Y, and Z are F, Cl, Br, I, H, OH, SH, SO₂H, SO₃H, SO₂NH₂, PO₃H₂, NO, NO₂, NH₂, CH₃, CHO, COCH₃, COOH, CONH₂, COCl, CN, CF₃, CCl₃, CBr₃, or CI₃; and
when desorption temperatures of X, Y and Z from carbon atoms constituting six-membered rings are respectively T_{X}, T_{Y}, and T_{Z}, a relationship of T_{X}<T_{Y}≤T_{Z} is satisfied.

2. A graphene nanoribbon having, as a repeat unit, a structure that is indicated by a following chemical formula (2), 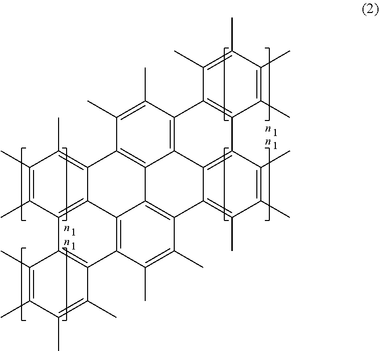
wherein an edge structure at both ends along a length direction is an armchair type, and
wherein in the above chemical formula (2), n₁ is an integer that is greater than or equal to 1 and less than or equal to 6.

3. The graphene nanoribbon according to claim 2, wherein a length is greater than or equal to 10 nm.

4. The graphene nanoribbon according to claim 2,
wherein the graphene nanoribbon has a first graphene nanoribbon area and a second graphene nanoribbon area,
wherein the first graphene nanoribbon area includes a first graphene nanoribbon having, as a repeat unit, a structure that is indicated by the above chemical formula (2), an edge structure at both ends of the first graphene nanoribbon along the length direction being an armchair type,
wherein the second graphene nanoribbon area includes a second graphene nanoribbon having, as a repeat unit, a structure that is indicated by the above chemical formula (2), an edge structure at both ends of the second graphene nanoribbon along the length direction being an armchair type,
wherein a value of n₁ of the first graphene nanoribbon is less than a value of n₁ of the second graphene nanoribbon, and
wherein the first graphene nanoribbon and the second graphene nanoribbon are hetero-joined via six-membered rings.

5. The graphene nanoribbon according to claim 4,
wherein the graphene nanoribbon has a third graphene nanoribbon area that includes a third graphene nanoribbon having, as a repeat unit, a structure that is indicated by the above chemical formula (2), an edge structure at both ends of the third graphene nanoribbon along the length direction being an armchair type,
wherein a value of n₁ of the third graphene nanoribbon is greater than the value of n₁ of the second graphene nanoribbon,
wherein the first graphene nanoribbon is hetero-joined via six-membered rings to both ends in the length direction of the second graphene nanoribbon, and
wherein the third graphene nanoribbon is hetero-joined via six-membered rings to ends of the first graphene nanoribbon opposite to the second graphene nanoribbon.

6. An electronic device comprising: the graphene nanoribbon according to claim 2 for a channel of a field effect transistor.

7. An electronic device comprising: the graphene nanoribbon according to claim 5 for a resonant tunneling diode.

8. A method of producing a graphene nanoribbon precursor, the method comprising:
causing a Suzuki coupling reaction between a first substance and a second substance to obtain a third substance, the first substance having a structure that is indicated by a following chemical formula (3), the second substance having a structure that is indicated by a following chemical formula (4), the third substance having a bond at a location of one iodine included in the first substance; and 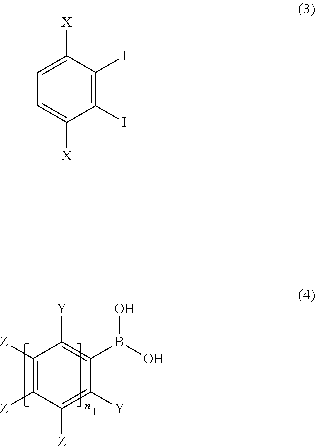
causing a Suzuki coupling reaction between the third substance and the second substance to obtain a fourth substance having a bond at a location of iodine included in the third substance,
wherein in the above chemical formulas (3) and (4),
n₁ is an integer that is greater than or equal to 1 and less than or equal to 6;
X, Y, and Z are F, Cl, Br, I, H, OH, SH, SO₂H, SO₃H, SO₂NH₂, PO₃H₂, NO, NO₂, NH₂, CH₃, CHO, COCH₃, COOH, CONH₂, COCl, CN, CF₃, CCl₃, CBr₃, or CI₃; and
when desorption temperatures of X, Y and Z from carbon atoms constituting six-membered rings are respectively T_{X}, T_{Y}, and T_{Y}, a relationship of T_{X}<T_{Y}≤T_{Z} is satisfied.

9. The method of producing the graphene nanoribbon precursor according to claim 8, wherein the second substance is a boronic acid of benzene, naphthalene, anthracene, naphthacene, pentacene or hexacene.

10. A method of producing a graphene nanoribbon, the method comprising:
heating graphene nanoribbon precursors according to claim 1 to a first temperature on a substrate to induce desorption of X and C—C bonding reaction to obtain a polymer on the substrate;
heating the polymer to a second temperature, which is higher than the first temperature, to induce desorption of Y and C—C bonding reaction; and
heating the polymer to a third temperature, which is equal to or higher than the second temperature, to induce desorption of Z and C—C bonding reaction.

11. The method of producing the graphene nanoribbon according to claim 10, wherein Y and Z are the same and the second temperature and the third temperature are equal to each other.

12. The method of producing the graphene nanoribbon according to claim 10,
wherein the graphene nanoribbon has a first graphene nanoribbon area and a second graphene nanoribbon area,
wherein the polymer is obtained on the substrate by
heating, in the first graphene nanoribbon area, the graphene nanoribbon precursors to the first temperature to induce the desorption of X and the C—C bonding reaction; and
heating, in the second graphene nanoribbon area, the graphene nanoribbon precursors to the first temperature to induce the desorption of X and the C—C bonding reaction,
wherein a value of n₁ of the graphene nanoribbon precursors, which are used for the first graphene nanoribbon area, is less than a value of n₁ of the graphene nanoribbon precursors, which are used for the second graphene nanoribbon area, and
wherein the first graphene nanoribbon, which is formed in the first graphene nanoribbon area, and the second graphene nanoribbon, which is formed in the second graphene nanoribbon area, are hetero-joined via six-membered rings.

13. The method of producing the graphene nanoribbon according to claim 12,
wherein the graphene nanoribbon has a third graphene nanoribbon area,
wherein the polymer is obtained on the substrate by heating, in the third graphene nanoribbon area, the graphene nanoribbon precursors to the first temperature to induce the desorption of X and the C—C bonding reaction,
wherein a value of n₁ of the graphene nanoribbon precursors, which are used for the third graphene nanoribbon area, is greater than the value of n₁ of the graphene nanoribbon precursors, which are used for the second graphene nanoribbon area, and
wherein the first graphene nanoribbon is hetero-joined via six-membered rings to both ends in a length direction of the second graphene nanoribbon, and
wherein the third graphene nanoribbon, which is formed in the third graphene nanoribbon area, is hetero-joined via six-membered rings to ends of the first graphene nanoribbon opposite to the second graphene nanoribbon.
